(19) United States
(12) Patent Application Publication
(10) Pub. No.: US 2010/0052951 A1
(43) Pub. Date: Mar. 4, 2010

(54) NINE SENSOR DATA ENTRY KEYBOARD AND CONTROL MEANS

(76) Inventor: James W. Burrell, IV, Union, NJ (US)

Correspondence Address: Ezra Sutton,P.A.;Plaza 9, Suite 201, 900 Route 9, Woodbridge, NJ, 07095-1024, US

(21) Appl. No.: 12/202,702

(22) Filed: Sep. 2, 2008

(51) Int. Cl. H03M 11/06

(52) U.S. Cl. 341/23

(57) ABSTRACT

This invention relates to methods of using nine sensors, preferably a centrally located sensor surrounded by eight adjacent sensors, to produce data. This invention also relates to methods of producing data using a multi-tap data entry method using nine sensors, a simultaneous data entry method using more than nine sensors and/or a sequential data entry method using more than nine sensors. This invention produces alphabetic data characters, data characters, a space, numbers, punctuation, symbols, control and functions using nine sensors or more than nine sensors. Activating one of nine sensors produces a number, a first data character of three or four data characters or multiple data characters. Activating one of nine sensors once produces a first data character, twice produces a second data character, thrice produces a third data character, four times produces a fourth data character, five times produces a fifth data character, six times produces a sixth data character, seven times produces a seventh data character, eight times or more produces additional data characters. The present invention relates to a method of using nine sensors for data entry, preferably on a centrally located sensor surrounded by eight adjacent cardinal point direction activated sensors or eight touch sensor cardinal point activated zones, a cell phone menu sensor, a camera menu sensor, an iPod/MP3 menu sensor, etc. for producing alphabetic data, a space, numbers, punctuation, symbols, control, functions and data characters; preferably activated by the left or right thumb. Nine sensors plus at least three additional sensors provide for simultaneous or sequential sensor activations, reducing the frequency of individual, simultaneous or sequential sensor activations. Nine sensors plus six additional sensors provide for simultaneous or sequential sensor activations which require fewer sensor activations than using only three additional sensors.

### FIELD OF THE INVENTION

The present invention relates to a method of using a nine sensor keyboard, preferably a centrally located sensor surrounded by eight adjacent cardinal point activated sensors or eight touch sensor cardinal point activated zones, a cell phone menu key, a camera menu key or an iPod/MP3 menu key, etc. for producing alphabetic data characters, data characters, a space, numbers, punctuation, symbols, control and functions, preferably activated by the left or right thumb. At least three additional sensors are used for simultaneous or sequential activation to provide a reduction in the number of key activations for producing alphanumeric data and a space. Six additional sensors are used for simultaneous or sequential activation to provide an even greater reduction in the number of key activations for producing alphanumeric data, a space, punctuation, symbols, control and functions.

### BACKGROUND OF THE INVENTION

Since the introduction of keyboards for producing alphanumeric data more than a hundred years ago, every number and alphabetic character was assigned its own key. Uppercase capital letters were produced using a shift key. Attempts to reduce the keyboard's size and the number of sensors used to produce alphanumeric data required using keyboards where each key produces more than one alphanumeric character. The least amount of sensors used to produce alphanumeric data in the well known prior art uses seven sensors, eight sensors or twelve sensors. There have also been keyboards using five and ten sensors, but they were never adopted into mainstream use. The following prior art references, which the inventor is aware of, are distinctly different from the present invention described in this patent application. The seven key keyboard used to produce six dot braille uses a chordic data entry method on six sensors and a seventh key to produce a space by the left or right thumbs. The eight key keyboard is used to produce six dot braille and eight dot braille. It uses a chordic data entry method on six or eight sensors. When producing six dot braille, the seventh and eighth keys are used by the left or right thumbs to produce a space. When the eight key keyboard is used to produce eight dot braille, it uses a chordic data entry method on all eight sensors.

Another eight key keyboard used to produce eight dot braille using an eight key chordic data entry method is found in U.S. Pat. No. 5,993,089 issued on Nov. 30, 1999 to Burrell, IV, titled “8-BIT BINARY CODE FOR USE AS AN 8-DOT BRAILLE ARRANGEMENT AND DATA ENTRY SYSTEM AND METHOD FOR 8-KEY CHORDIC BINARY KEYBOARDS”. Burrell, IV teaches a chordic data entry system and method to enter all Latin based alphabets and all computer data using only eight sensors. The keyboard can also be adapted to enter all alphabets used throughout the world and all Unicode data.

The twelve key keyboard uses a phone keypad to produce alphanumeric data. Alphabetic characters are produced using sensors 1 through 9 or sensors 2 through 9. The fastest and most efficient method of producing alphanumeric data requiring the least amount of key activations on a phone is found in U.S. Pat. No. 6,043,761 issued on Mar. 28, 2000 to Burrell, IV, titled “METHOD OF USING A NINE KEY ALPHANUMERIC BINARY KEYBOARD COMBINED WITH A THREE KEY BINARY CONTROL KEYBOARD”, U.S. Pat. No. 6,184,803 issued on Feb. 6, 2001 to Burrell, IV, titled “NINE KEY ALPHANUMERIC BINARY KEYBOARD COMBINED WITH A THREE KEY BINARY CONTROL KEYBOARD AND COMBINATIONAL CONTROL MEANS” and in U.S. Pat. No. 6,232,892 issued on May 15, 2001 to Burrell, IV, titled “METHOD OF USING A NINE KEY ALPHANUMERIC BINARY KEYBOARD COMBINED WITH A THREE KEY BINARY CONTROL KEYBOARD”. A partial demonstration of the Burrell, IV twelve key keyboard can be found on the www.phonekeyboard.com website along with the data entry statistics. Other slower twelve key keyboard alphanumeric data entry methods requiring the more key activations are T9 introduced by Tegic, iTAP introduced by Motorola and eZiText introduced by ZI Corp.

Many solutions to improve many of the existing prior art problems have been made, but many are not well suited for the blind community, the deaf-blind community and for an individual needing to enter alphabetic data into a data entry device without looking at the keyboard entry device. A method of alphanumeric data entry into a data entry keyboard device which does not require visual assistance is needed. The invention disclosed in this patent application fulfills this need.

### SUMMARY OF THE INVENTION

The present invention produces alphabetic data characters, data characters, a space, numbers, punctuation, symbols, control and functions using a centrally located sensor surrounded by eight adjacent cardinal point activated sensors, or a centrally located sensor surrounded by eight adjacent juxtaposed trapezoidal shaped cardinal point activated sensors, or a centrally located sensor surrounded by circular shaped sensor with eight touch sensor cardinal point activated zones. The use of a centrally located sensor surrounded by eight adjacent sensors activated by only one finger, preferably the thumb digit, produces the world's smallest data entry keyboard. Activating a centrally located sensor or one of the eight adjacent cardinal point activated sensors once, twice, thrice, etc. produces the desired data. This method of producing data or text messaging can be used on a phone menu key, a camera menu key or an iPod/MP3 menu key. Combining the thumb keyboard with the applicant's three issued patents; U.S. Pat. No. 6,043,761, U.S. Pat. No. 6,184,803 and U.S. Pat. No. 6,232,892 produces a method of text messaging on any device faster than all prior art devices using any disclosed prior art. The present invention can use any of the prior art text messaging methods, but the applicant's three issued patents are the preferred input method due to the reduction in sensor activations required to produce data.

One preferred embodiment of the present invention uses a method of using a nine sensor keyboard for producing alphabetic data characters, data characters, a space, numbers, punctuation, symbols, control and functions using a centrally located touch activated sensor surrounded by eight adjacent cardinal point activated touch sensors. Activating a centrally located sensor or one of the eight adjacent sensors once produces the first preferably left position data, twice produces the second preferably middle position data and thrice produces the third preferably right position data, etc. Alternatively, activating a centrally located sensor or one of the eight adjacent sensors combined with the simultaneous activation of or followed by the sequential activation of a left preferred asterisk [*] sensor produces the first preferably left position data, activation of a middle preferred zero [0] sensor produces the second preferably middle position data, or activation of a right preferred number [#] sensor produces the third preferably right position data. Secondary activation of the second sensor, produces an upper-case letter.

Activating one of the eight adjacent sensors surrounding the centrally located sensor or the centrally located sensors eight times or more produces even more data characters, control or functions. Programming the device to produce the user's preferred data characters using preferred key activations is also possible.

Another preferred embodiment of the present invention uses a method of using a nine sensor keyboard for producing numbers one through nine, at least twenty-six data characters or letters of an alphabet and a space, punctuation and symbols using a centrally located touch activated sensor surrounded by eight adjacent touch activated sensors. Activating a centrally located sensor or one of the eight adjacent sensors once produces numbers one through nine, twice produces the first preferably left position data, thrice produces the second preferably middle position data and four times produces the third preferably right position data, etc. Alternatively, activating a centrally located sensor or one of the eight adjacent sensors combined with the simultaneous activation of or followed by the sequential activation of a left preferred asterisk [*] sensor produces the first preferably left position data, activation of a middle preferred zero [0] sensor produces the second preferably middle position data, or activation of a right preferred number [#] sensor produces the third preferably right position data. Secondary activation of the second sensor, produces an upper-case letter.

Activating one of the eight adjacent sensors surrounding the centrally located sensor or the centrally located sensors eight times or more produces even more data characters, control or functions. Programming the device to produce the user's preferred data characters using preferred key activations is also possible.

Another preferred embodiment of the present invention uses a method of using a nine sensor keyboard for producing numbers one through nine, at least twenty-six data characters or letters of an alphabet and a space, punctuation and symbols using a centrally located touch activated sensor surrounded by eight adjacent touch activated sensors. Activating a centrally located sensor or one of the eight adjacent sensors once produces numbers one through nine. Alternatively, activating a centrally located sensor or one of the eight adjacent sensors combined with the simultaneous activation of or followed by the sequential activation of a left preferred asterisk [*] sensor produces the first preferably left position data, activation of a middle preferred zero [0] sensor produces the second preferably middle position data, or activation of a right preferred number [#] sensor produces the third preferably right position data. Secondary activation of the second sensor, produces an upper-case letter. Activating a centrally located sensor or one of the eight adjacent sensors combined with the simultaneous activation of or followed by the sequential activation of a left sensor ([1], [4] or [7]) produces the left position data, activation of a middle sensor ([2], [5] or [8]) produces the middle position data, or activation of a right sensor ([3], [6] or [9]) produces the right position data.

Extra punctuation marks, symbols and functions are produced by activating the centrally located sensor or one of the eight adjacent sensors surrounding the centrally located sensor in eight cardinal point directions more than one time.

Alternatively, any letter data, numeric data, punctuation data, symbol data or any other type of data or character substitution can be made or used for the present invention's described text input methods and alternative preferred embodiments.

In another preferred embodiment of the present invention, when using the centrally located sensor surrounded by eight adjacent sensors to produce data on a phone or cell phone, activating any sensor other than the centrally located sensor surrounded by eight adjacent sensors enters the entered data for the production of the next data character located on the same sensor as the previously entered data character.

In another preferred embodiment of the present invention, activating a centrally located sensor or one of the eight adjacent sensors combined with the simultaneous activation of or followed by the sequential activation of a left preferred [1], [4], [7] or [*] sensor produces the first preferably left position data, activation of a middle preferred [2], [5], [8] or [0] sensor produces the second preferably middle position data, or activation of a right preferred [3], [6], [9] or [#] sensor produces the third preferably right position data.

In another preferred embodiment of the present invention, when using the centrally located sensor surrounded by eight adjacent sensors to produce data on a phone or cell phone, activating the left preferred asterisk [*] sensor when using only the centrally located sensor surrounded by eight adjacent sensors to produce alphabetic data, while in an alphabetic multi-tap mode, produces an upper-case data character.

In another preferred embodiment of the present invention, when using the centrally located sensor surrounded by eight adjacent sensors to produce data on a phone or cell phone, activating the left preferred asterisk [*] sensor once produces a period “.”, activating the middle preferred zero [0] sensor once produces a space “ ”, activating the right preferred number [#] sensor once produces a hyphen “-”.

In another preferred embodiment of the present invention, numbers are produced by activating one of the ten numbered sensors.

In another preferred embodiment of the present invention, to produce a backspace while in the number mode, the right preferred number [#] sensor is activated once, when it is not followed by the sequential activation of a first left preferred asterisk [*] sensor or a second middle preferred zero [0] sensor.

In another preferred embodiment of the present invention, activation of the right preferred number [#] sensor three times, while in the alphanumeric mode, produces the “ENTER/RETURN/SEND” function.

In another preferred embodiment of the present invention, activation of the left preferred asterisk [*] sensor, while in the number mode, when not followed by the sequential activation of middle preferred zero [0] sensor or the activation of the right preferred number [#] sensor, exits the number mode and enters an alphabet mode.

In another preferred embodiment of the present invention, activation of the left preferred asterisk [*] sensor followed by the secondary activation of the left preferred asterisk [*] sensor, when not followed by the sequential activation of middle preferred zero [0] sensor or the activation of the right preferred number [#] sensor, while in the number mode, exits the number mode and enters a two sensor lower-case alphabet mode and a three sensor upper-case alphabet mode, where the secondary activation of the second sensor produces the upper-case character.

In another preferred embodiment of the present invention, activation of the middle preferred zero [0] sensor two times, while in an alphabetic mode, produces the “TAB” function.

In another preferred embodiment of the present invention, activation of the left preferred asterisk [*] sensor, while in an alphabetic mode, followed by the left preferred asterisk [*] sensor, deletes the previously-entered bit of data, otherwise known as the backspace.

In another preferred embodiment of the present invention, activation of the left preferred asterisk [*] sensor three times, while in an alphabetic mode, deletes the previously entered word.

In another preferred embodiment of the present invention, activation of the left preferred asterisk [*] sensor, while in an alphabetic mode, combined with the simultaneous activation of or followed by the sequential activation of the middle preferred zero [0] sensor produces a period “.”.

In another preferred embodiment of the present invention, activation of the left preferred asterisk [*] sensor, while in the alphabetic mode, combined with the simultaneous activation of or followed by the sequential activation of the activation of the right preferred number [#] sensor enters a one-time use punctuation mode, followed by the desired punctuation data sensor representation of the ten sensors numbered one [1] through zero [0].

In another preferred embodiment of the present invention, activation of the right preferred number [#] sensor combined with the simultaneous activation of or followed by the sequential activation of the middle preferred zero [0] sensor, while in the alphabetic mode, returns the keyboard to the number mode.

It is an object of the present invention to provide a complete data entry method using a centrally located sensor surrounded by eight adjacent sensors.

It is another object of the present invention to provide a complete data entry method using a cell phone menu key.

It is still another object of the present invention to provide a complete data entry method using a camera menu key.

It is yet another object of the present invention to provide a complete data entry method using an iPod/MP3 menu key.

It is a further object of the present invention to provide a simultaneous data entry method using a cell phone menu key combined with the simultaneous activation of three or six other sensors.

Finally, it is another object of the present invention to provide a sequential data entry method using a cell phone menu key combined with the sequential activation of three or six other sensors.

The present invention and many preferred embodiments of the present invention all use a centrally located sensor surrounded by eight adjacent sensors.

These and other objects, features and advantages of the present invention are provided within this patent application and will be better understood in connection with the following drawings and descriptions of the preferred embodiments. Additional objects of the present invention will become apparent as the description proceeds.

It is to be understood that the present invention is not limited in its application to the details of construction and to the arrangements of the components set forth in the following description or illustrated in the drawings. The present invention is capable of other embodiments and of being practiced and carried out in various ways. It should be also understood that the phraseology and terminology used in this patent application are for the purpose of describing and claiming the present invention and should not be regarded as limiting.

### DESCRIPTION OF THE DRAWINGS

For a better understanding of the invention as well as other objects, features and advantages thereof, reference is made to the following detailed description to be read in conjunction with the accompanying drawings, wherein:

FIG. 1 shows a top view of the present invention, depicting a nine sensor keyboard where a centrally located sensor is surrounded by eight adjacent and juxtaposed trapezoidal shaped sensors.

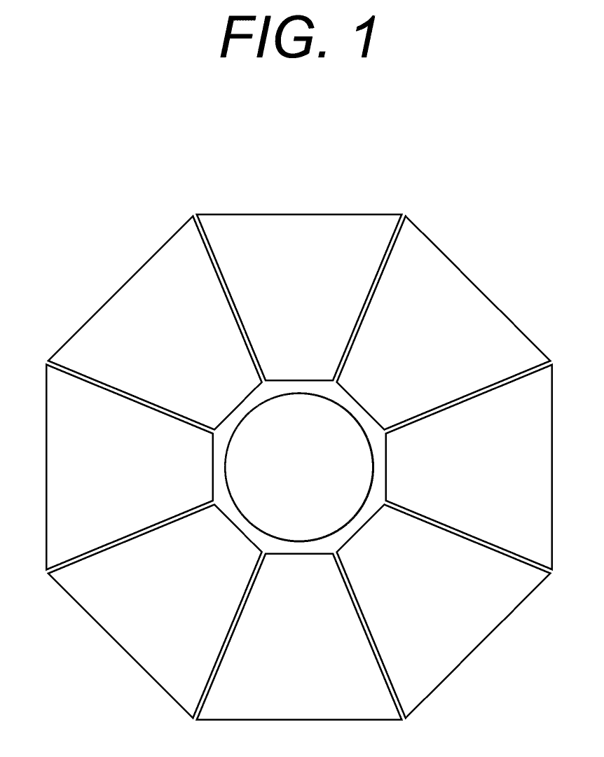

FIG. 2 shows a top view of the present invention, depicting a nine sensor keyboard where a centrally located sensor is surrounded by a disc shaped sensor with eight surfaces for activation in eight cardinal point directions.

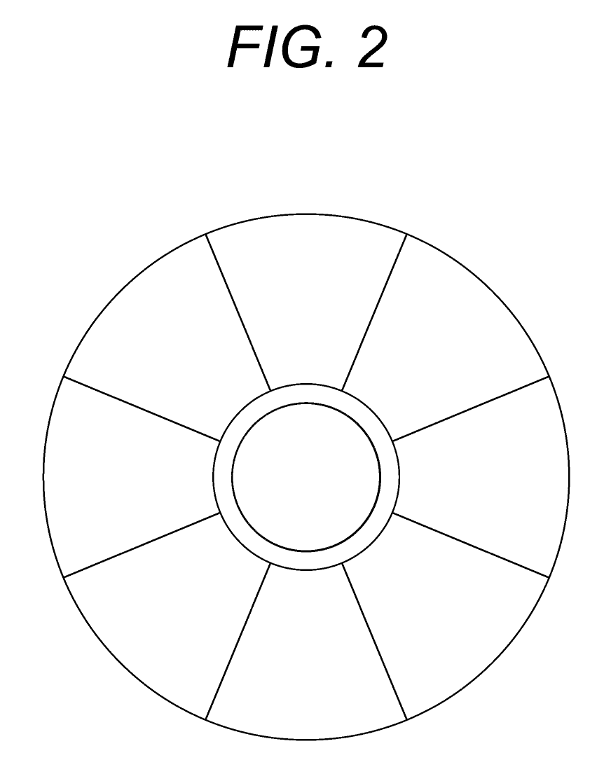

FIG. 3 shows a top view of the present invention, depicting a nine sensor keyboard where a centrally located sensor is surrounded by a disc shaped sensor with an octagonal shaped interior and eight surfaces for activation in eight cardinal point directions.

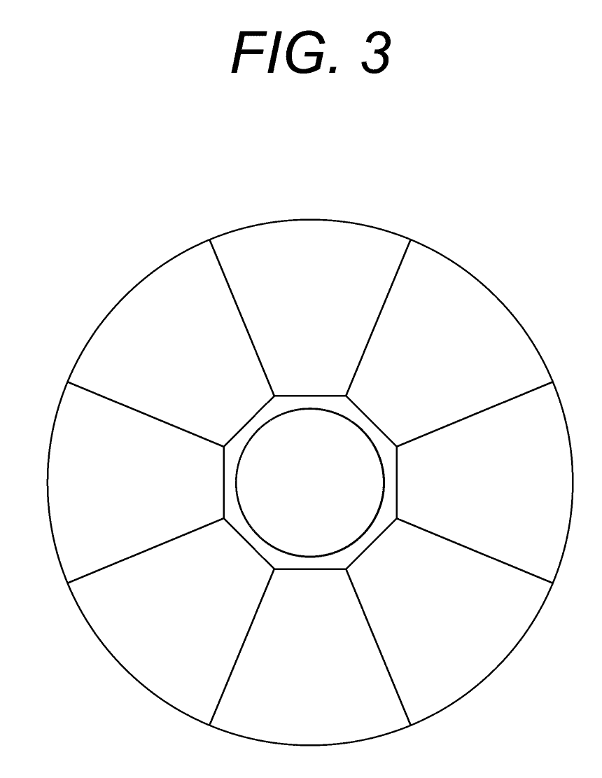

FIG. 4 shows a top view of the present invention, depicting a nine sensor keyboard where a centrally located sensor is surrounded by a octagon shaped sensor with an octagonal shaped interior and eight surfaces for activation in eight cardinal point directions.

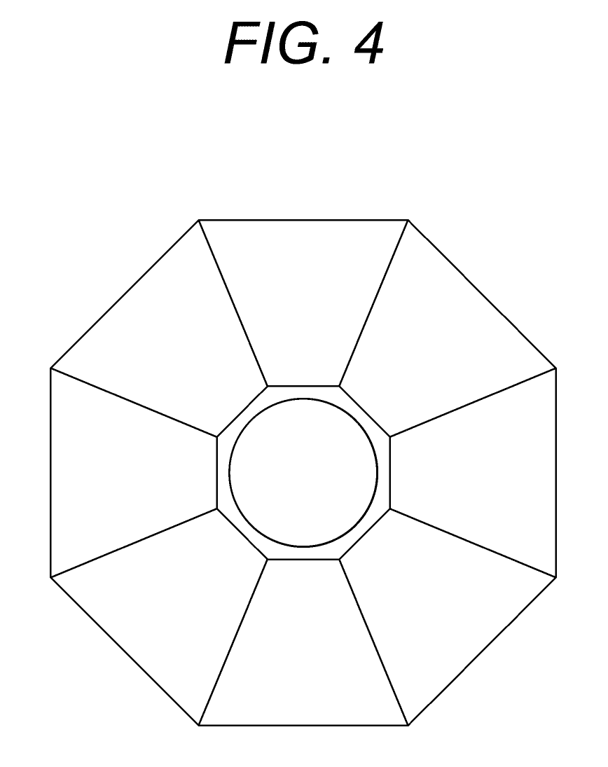

FIG. 5 shows a cross sectional view of the present invention, depicting a nine sensor keyboard where a centrally located sensor is surrounded by an eight sensors or a sensor with eight surfaces for activation in eight cardinal point directions. Each of the eight sensors or sensor with eight surfaces for activation in eight cardinal point directions preferably slopes downward from the outside edge toward the centrally located center sensor.

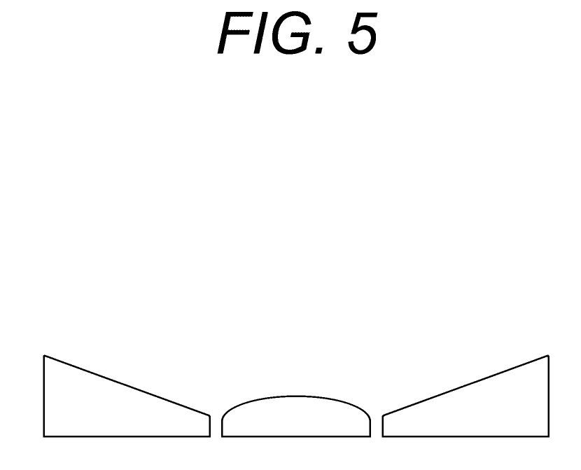

FIG. 6 shows a top view of the present invention, depicting a nine sensor keyboard where a centrally located sensor is surrounded by a octagon shaped sensor with an octagonal shaped interior and eight surfaces for activation in eight cardinal point directions or in sixteen cardinal point directions by activating two adjacent sensors simultaneously.

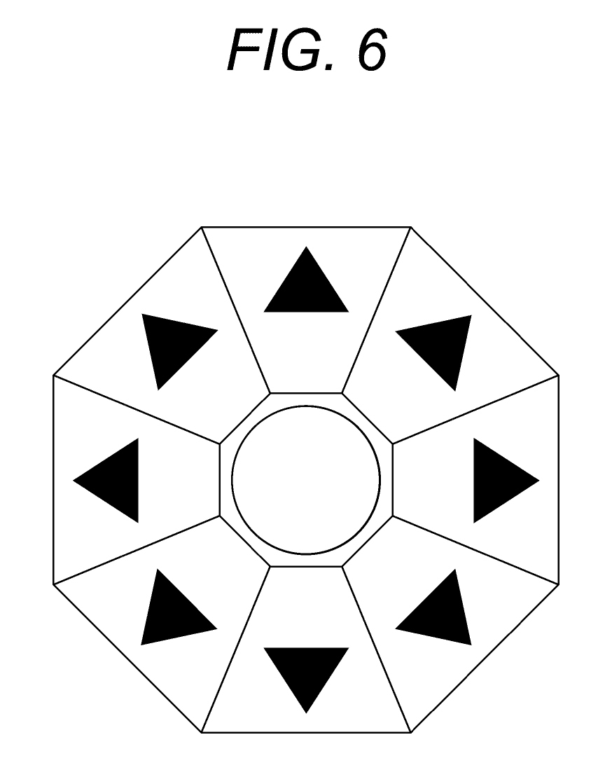

FIG. 7 shows a top view of the present invention, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement. Three additional sensors are labeled with the asterisk, zero and number sign.

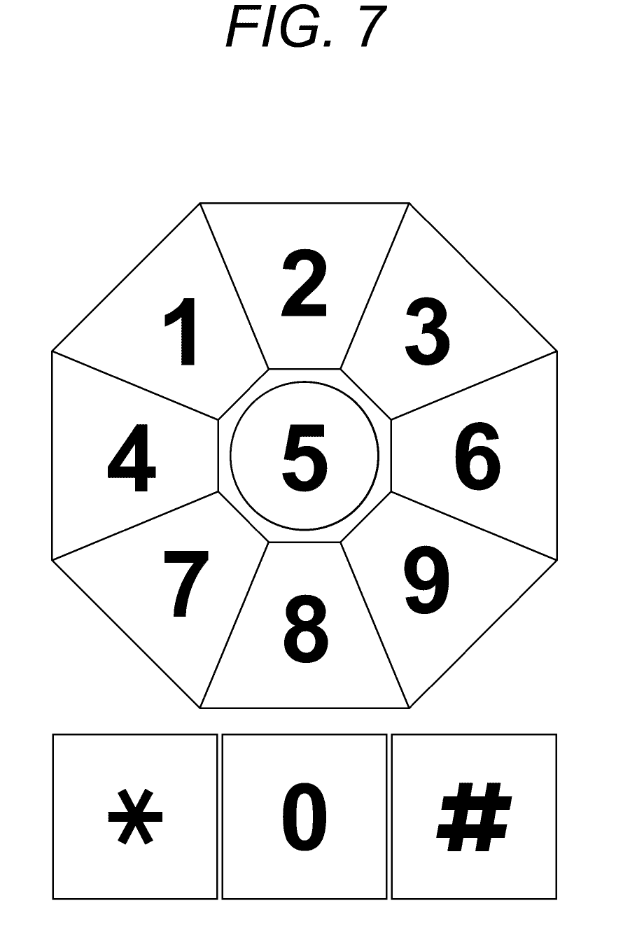

FIG. 8 shows a top view of the present invention, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Three additional sensors are labeled with the asterisk, zero and number sign.

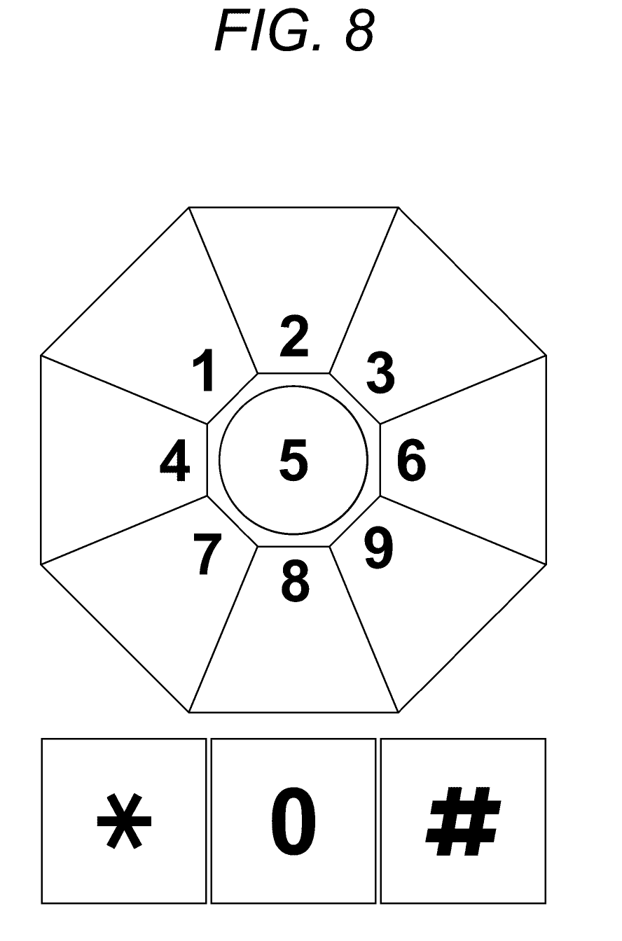

FIG. 9 shows a top view of the present invention, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Each of the nine sensors is labeled with three of twenty-six alphabetic characters and a space. Three additional sensors are labeled with the asterisk, zero and number sign.

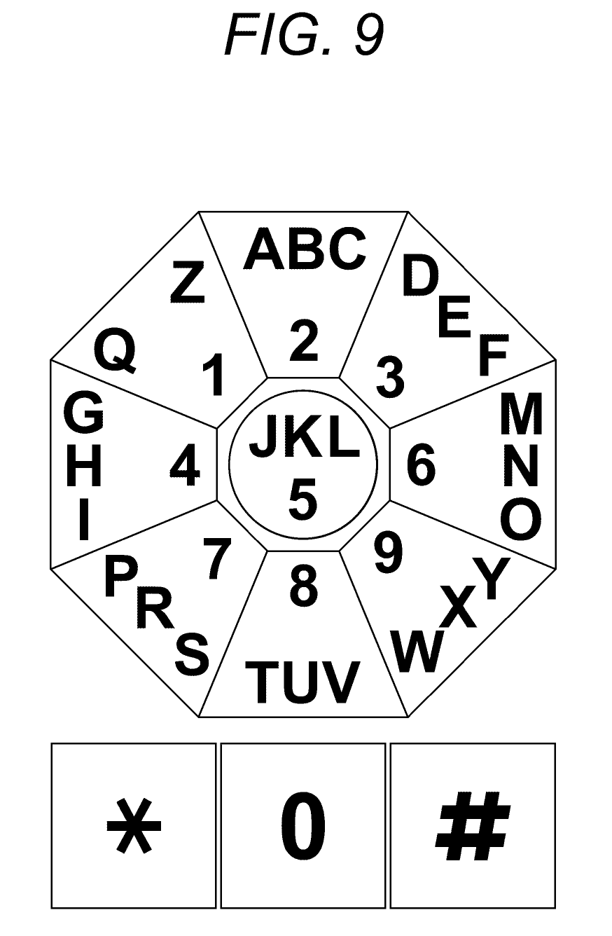

FIG. 10 shows a top view of the present invention, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Each of the nine sensors is labeled with three of twenty-six alphabetic characters and a space. Each of the nine sensors is also labeled with three punctuation marks or symbols. Three additional sensors are labeled with the asterisk, zero and number sign. The zero sensor also is also labeled with three punctuation marks or symbols.

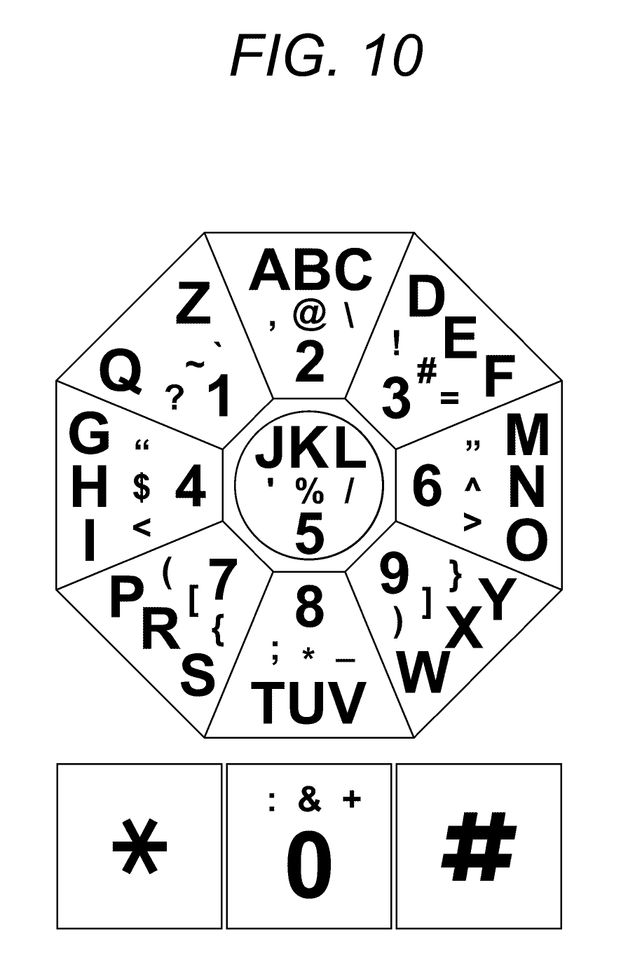

FIG. 11 shows a top view of the present invention, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Each of the nine sensors is labeled with three of twenty-six alphabetic characters and a space. Each of the nine sensors is also labeled with three punctuation marks or symbols. The sensor numbered one is labeled with the space and two alphabetic characters. Three additional sensors are labeled with the asterisk, zero and number sign. The zero sensor also is also labeled with three punctuation marks or symbols.

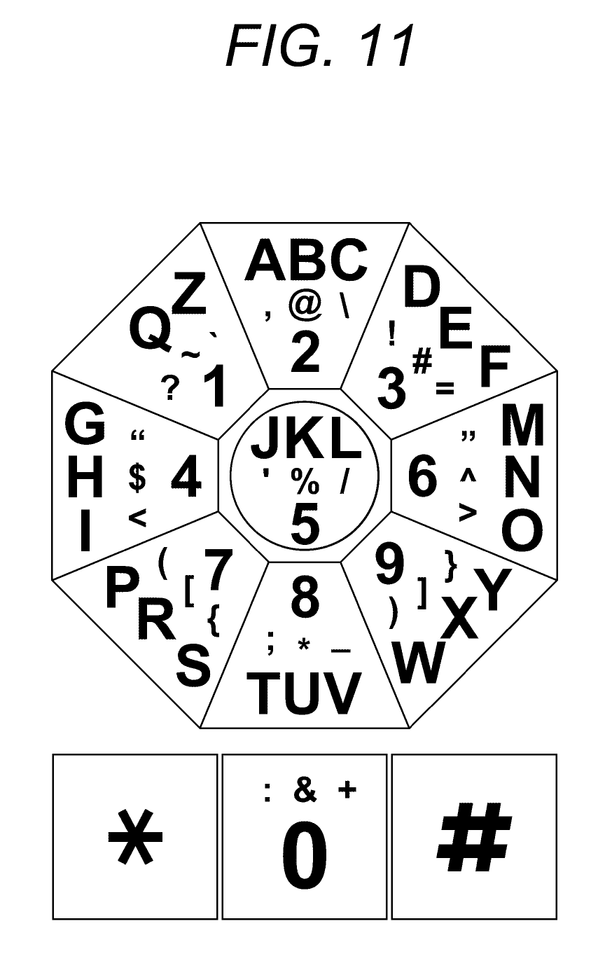

Prior art cell phone keyboards have been adapted for use with the present invention and have been included for reference:

FIG. 12 shows a top view of the present invention, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign.

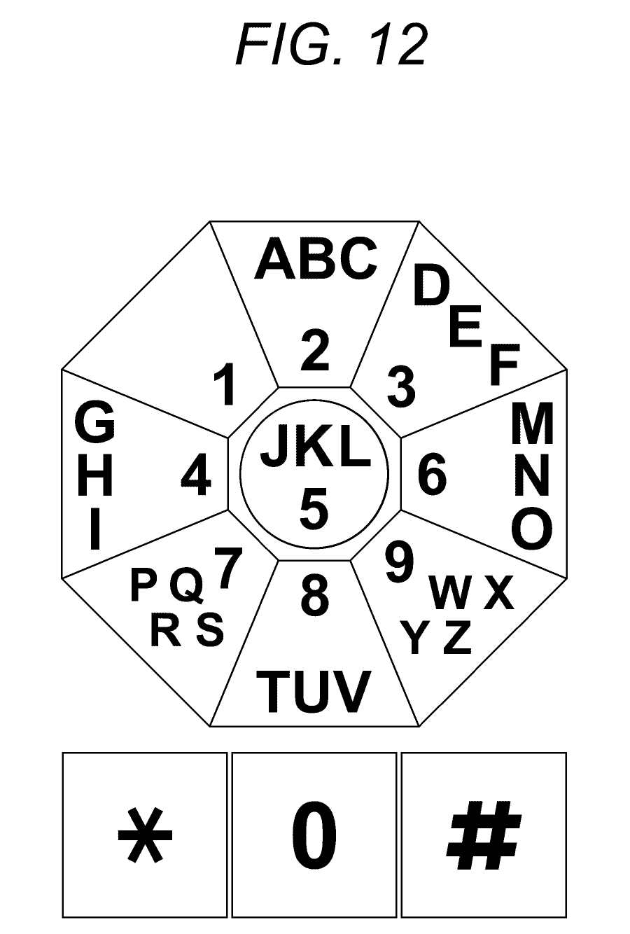

FIG. 13 shows a top view of the present invention using the prior art iPhone phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The zero sensor is labeled with the plus sign.

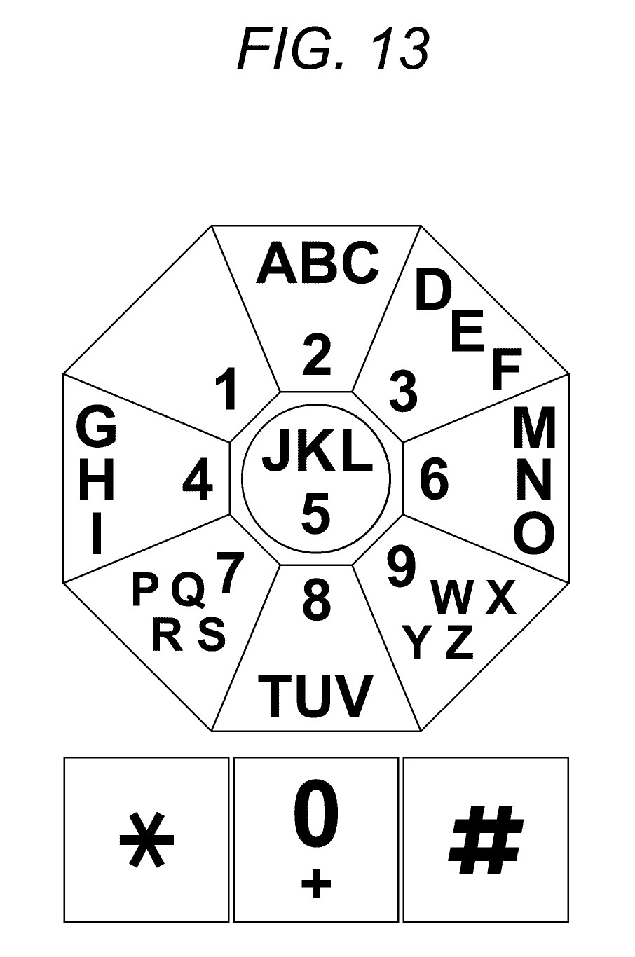

FIG. 14 shows a top view of the present invention using a prior art LG cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with the shift function. The zero sensor is labeled with the plus sign and the next function. The number sign sensor is labeled with the space function.

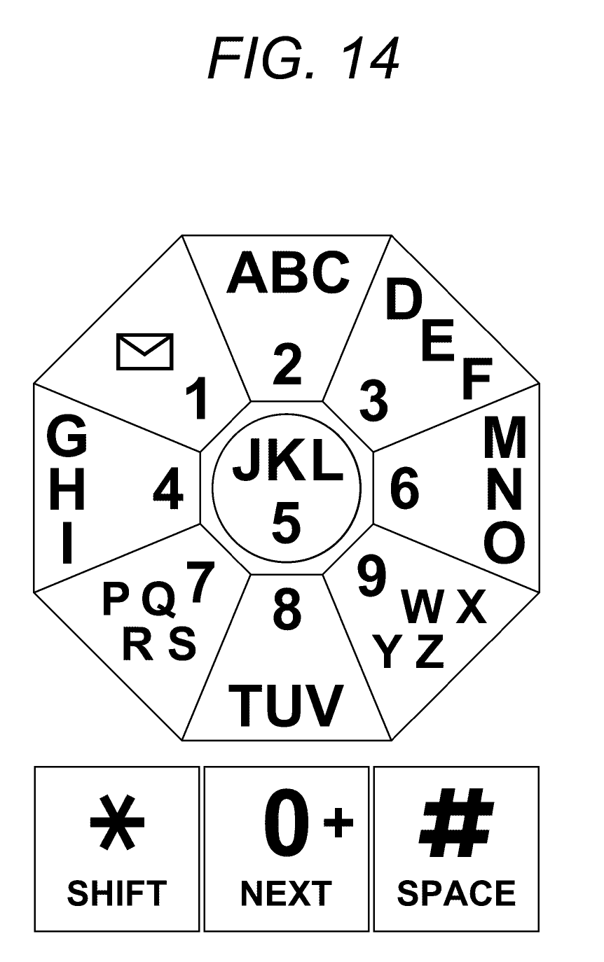

FIG. 15 shows a top view of the present invention using another prior art LG cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. The sensor numbered one is also labeled with the at “@” symbol. Three additional sensors are labeled with the asterisk, zero and number sign. The asterisk sensor is labeled with the shift function. The number sign sensor is labeled with the space function.

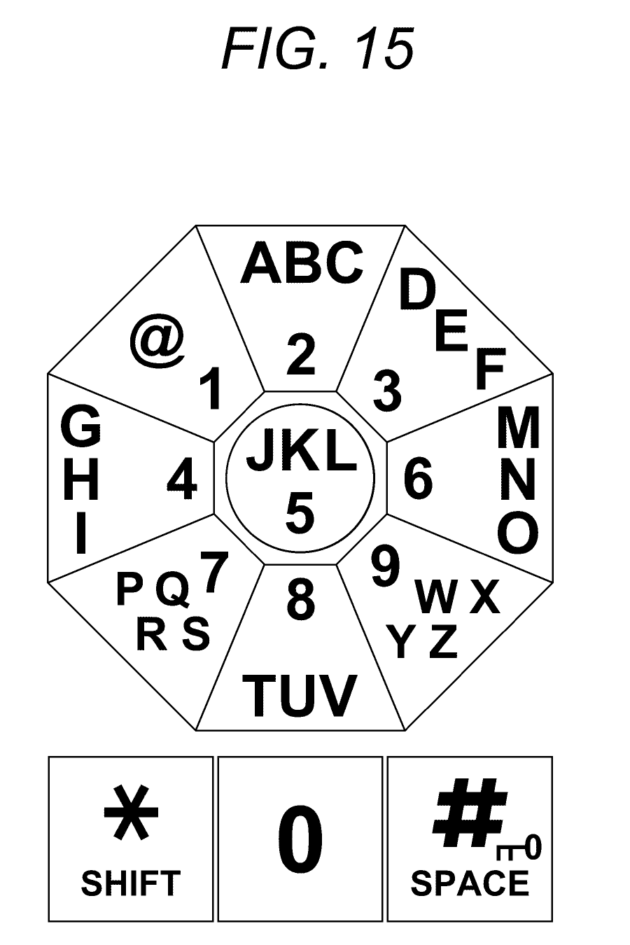

FIG. 16 shows a top view of the present invention using yet another prior art LG cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with the period and comma. The zero sensor is labeled with the plus sign and the space function. The number sign sensor is labeled with the shift function.

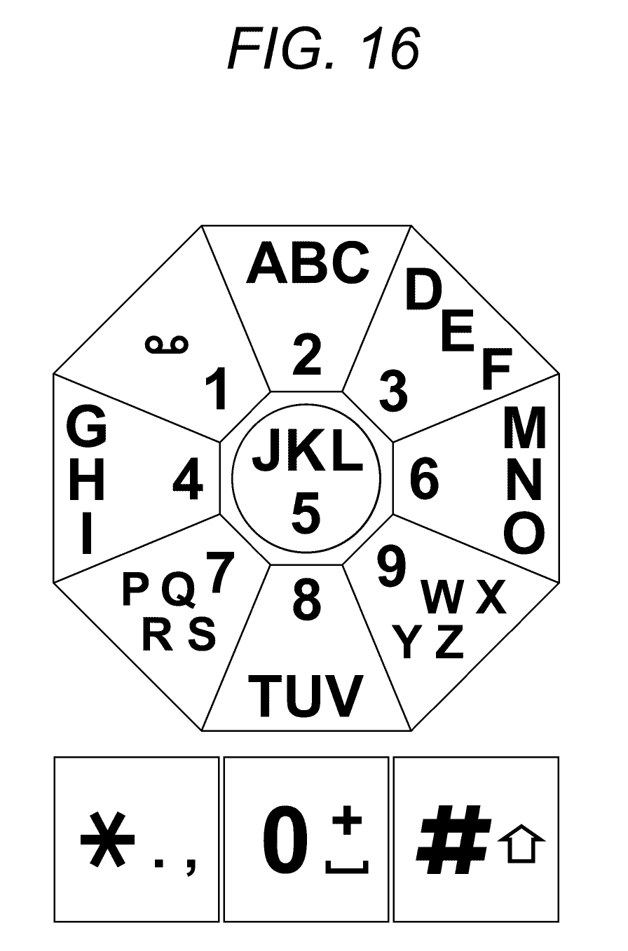

FIG. 17 shows a top view of the present invention using a prior art Motorola cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. The sensor numbered one is also labeled with the underscore “_”, comma “,” and at “@” symbol. Three additional sensors are labeled with the asterisk “*”, zero “0” and number sign “#”. The zero sensor is labeled with the plus sign “+”.

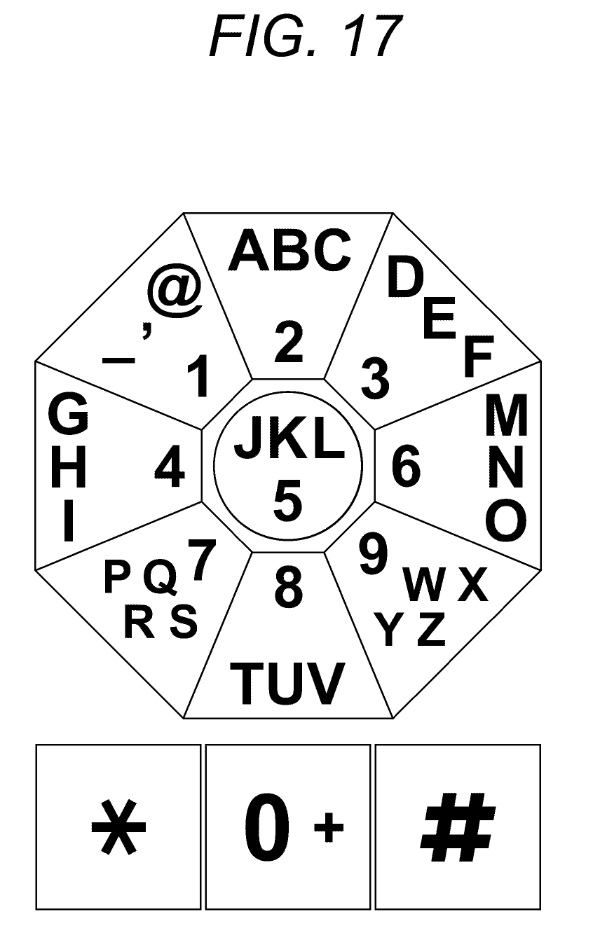

FIG. 18 shows a top view of the present invention using another prior art Motorola cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. The sensor numbered one is also labeled with the underscore, comma and at “@” symbol. Three additional sensors are labeled with the asterisk, zero and number sign. The zero sensor is labeled with the shift function. The number sign sensor is labeled with the space function.

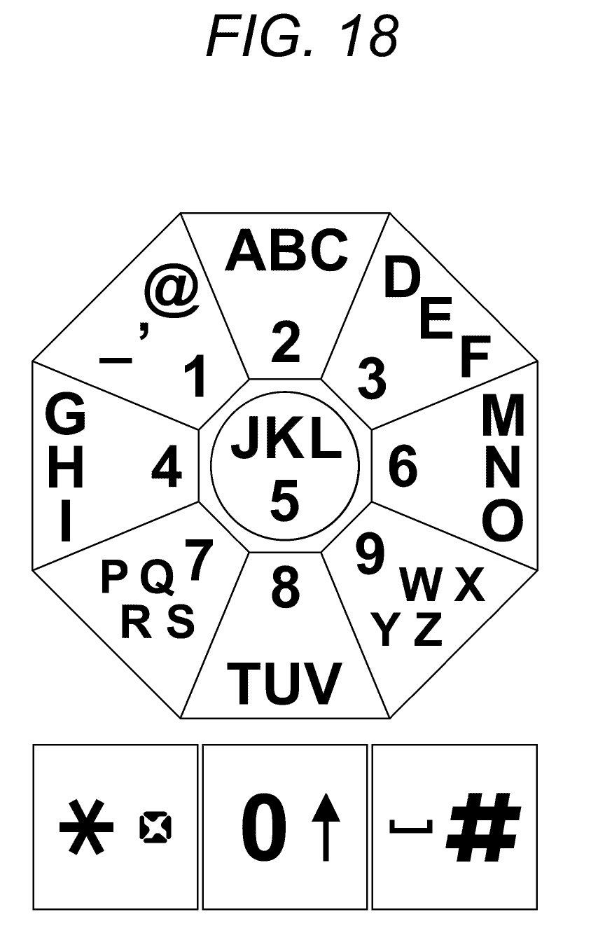

FIG. 19 shows a top view of the present invention using yet another prior art Motorola cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. The sensor numbered one is also labeled with the underscore, comma and at “@” symbol. Three additional sensors are labeled with the asterisk, zero and number sign. The asterisk sensor is labeled with the shift function. The zero sensor is labeled with the plus sign. The number sign sensor is labeled with the space function.

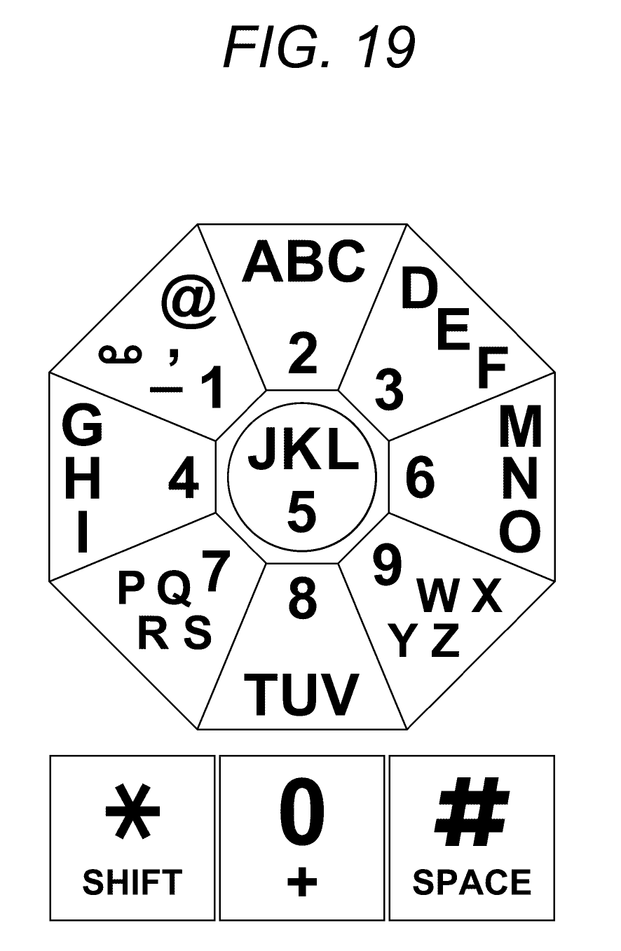

FIG. 20 shows a top view of the present invention using still another prior art Motorola cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. The sensor numbered one is also labeled with the underscore, comma and at “@” symbol. Three additional sensors are labeled with the asterisk, zero and number sign. The asterisk sensor is labeled with the shift function. The zero sensor is labeled with the plus sign. The number sign sensor is labeled with the space function.

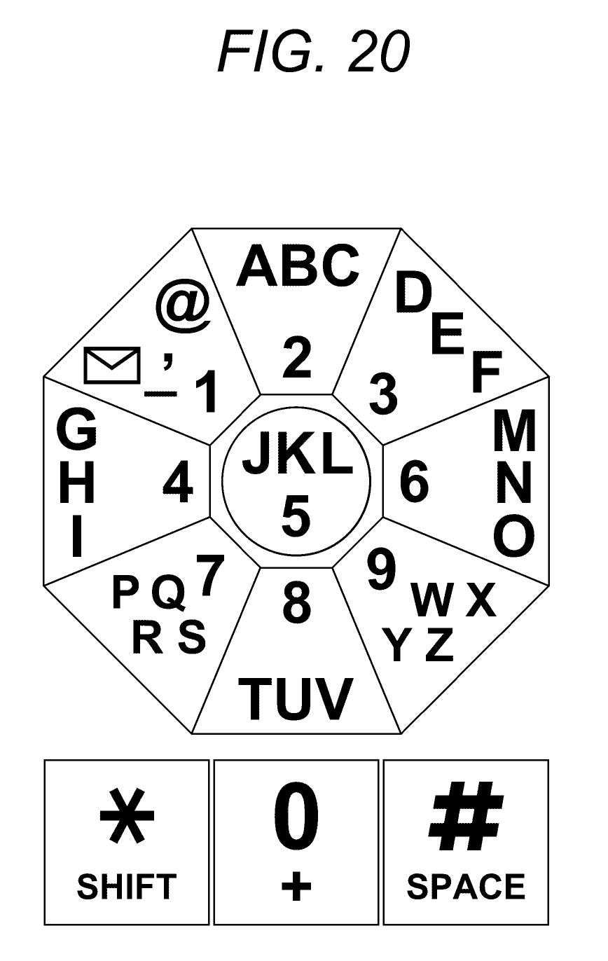

FIG. 21 shows a top view of the present invention using a prior art Nokia cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with a plus sign. The zero sensor is labeled with the space function. The number sign sensor is labeled with the shift function.

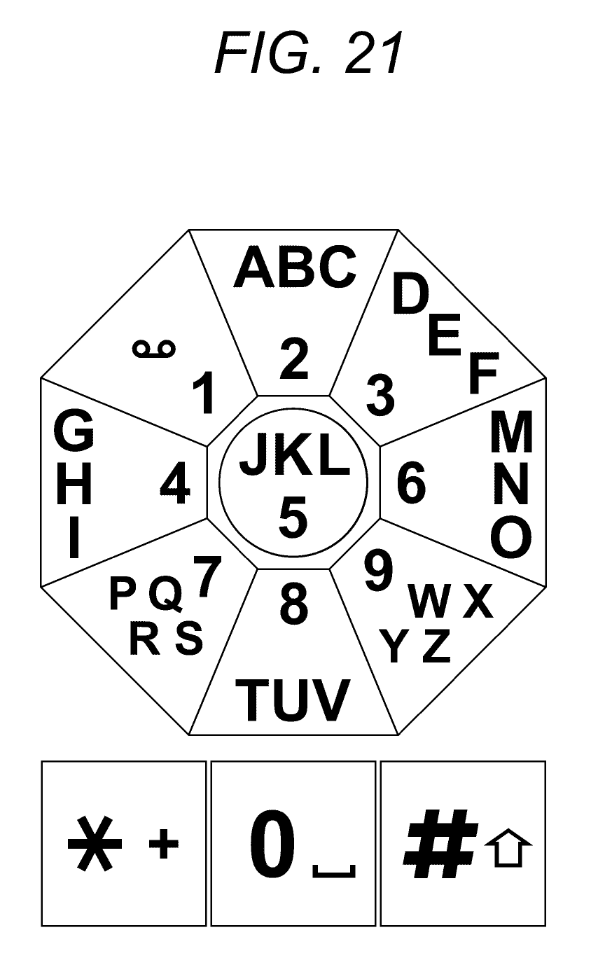

FIG. 22 shows a top view of the present invention using a prior art Samsung cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with a shift function. The zero sensor is labeled with the plus sign. The number sign sensor is labeled with the space function.

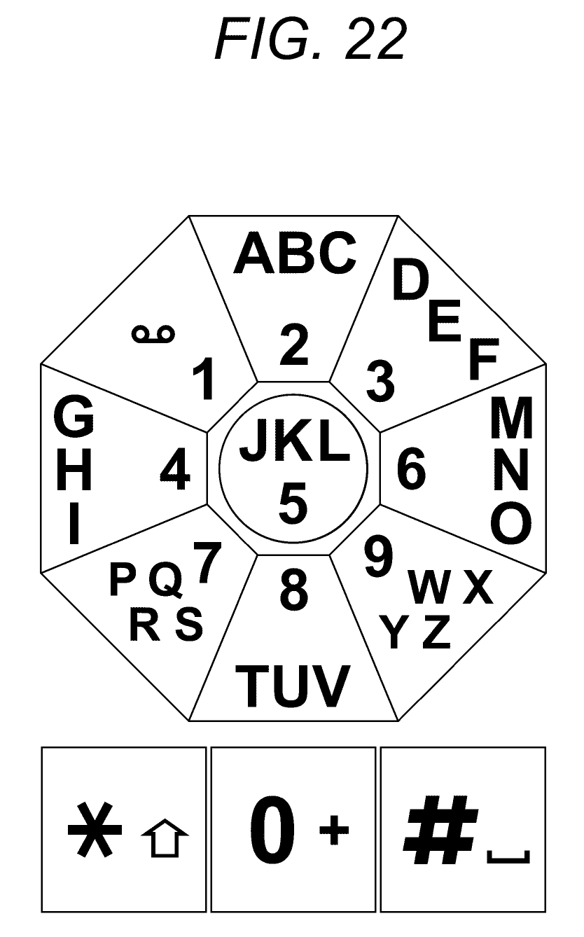

FIG. 23 shows a top view of the present invention using another prior art Samsung cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with a shift function and the plus sign. The number sign sensor is labeled with the space function.

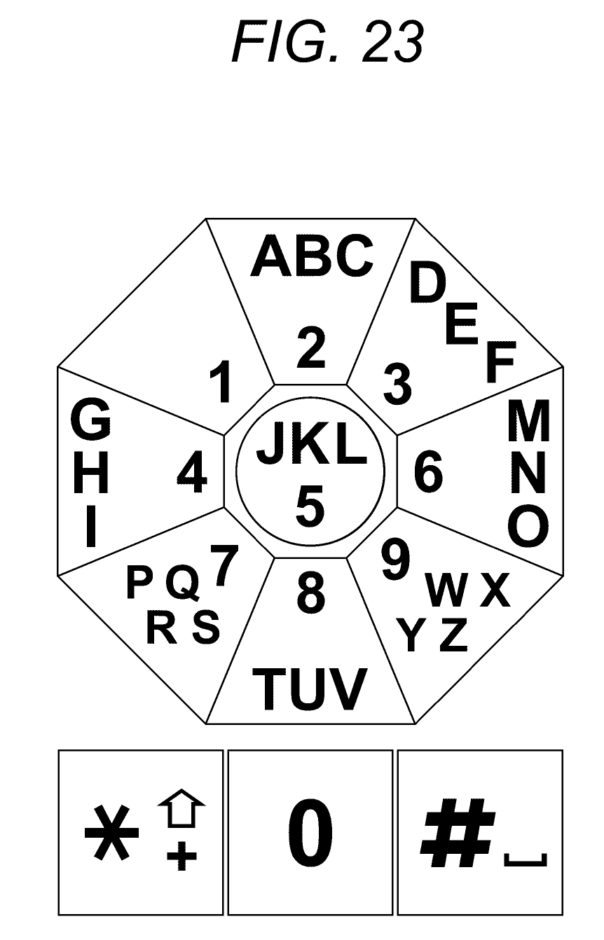

FIG. 24 shows a top view of the present invention using a prior art Sanyo cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with a shift function. The zero sensor is labeled with the plus sign. The number sign sensor is labeled with the space function.

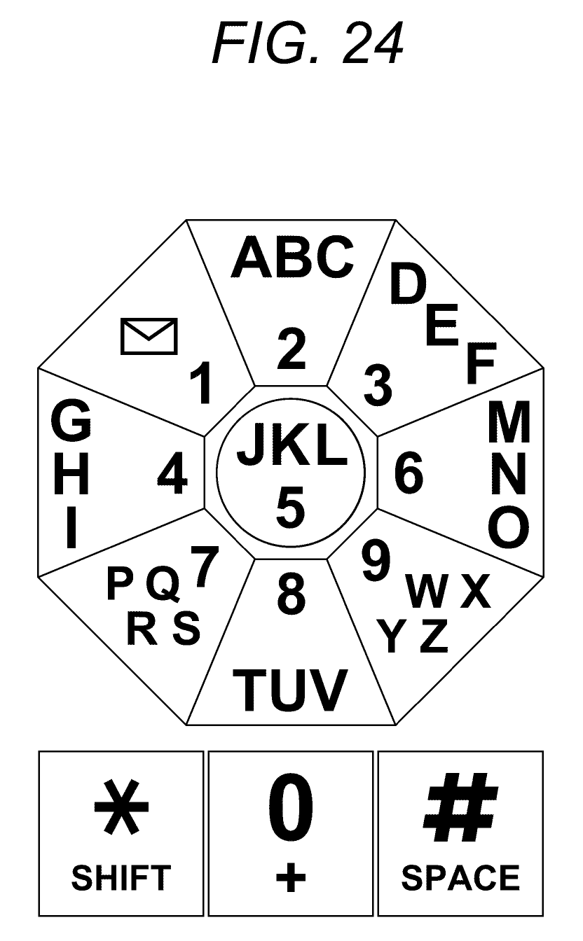

FIG. 25 shows a top view of the present invention using a prior art Sony Ericsson cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with a shift function. The zero sensor is labeled with the plus sign. The number sign sensor is labeled with the space function.

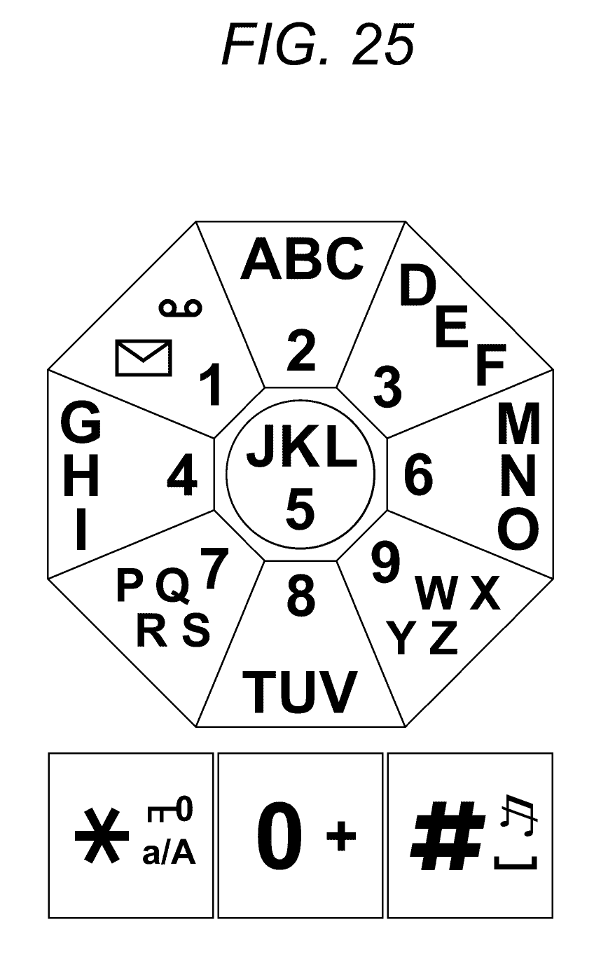

FIG. 26 shows a top view of the present invention using a prior art Tegic T9 cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with a plus sign. The zero sensor is labeled with the space function. The number sign sensor is labeled with the shift function.

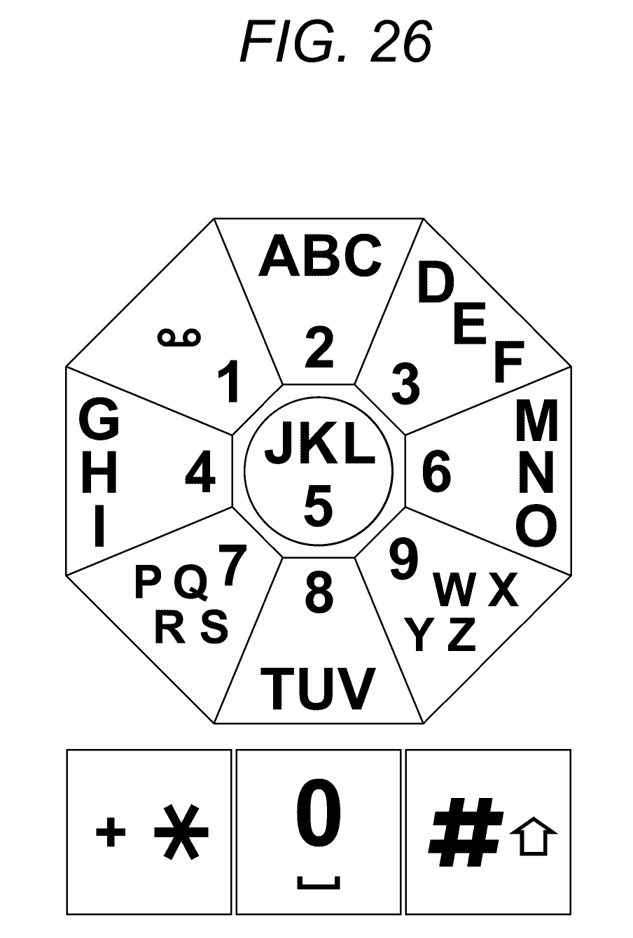

FIG. 27 shows a top view of the present invention using another prior art cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. The sensor numbered one is also labeled with the at “@” symbol. Three additional sensors are labeled with the asterisk, zero and number sign. The asterisk sensor is labeled with a shift function and the plus sign. The number sign sensor is labeled with the space function.

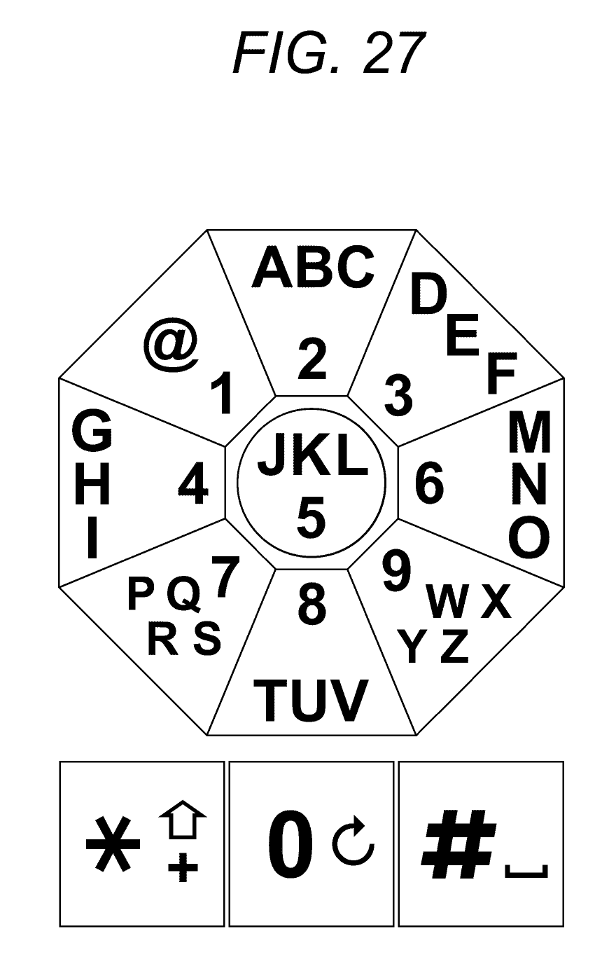

FIG. 28 shows a top view of the present invention using yet another prior art cell phone keypad labeling scheme, depicting a nine sensor keyboard where a centrally located sensor is surrounded by a octagon shaped sensor with an octagonal shaped interior and eight surfaces for activation in eight cardinal point directions. Each of the nine sensors is numbered one through nine using the standard phone keypad numbering arrangement allowing for the placement of additional characters. Six of the nine sensors are labeled with three of twenty-six alphabetic characters. Two of the nine sensors are labeled with four of twenty-six alphabetic characters. Three additional sensors are labeled with the asterisk, zero and number sign. The asterisk sensor is labeled with the T9 function. The zero sensor is labeled with the plus sign. The number sign sensor is labeled with the space function.

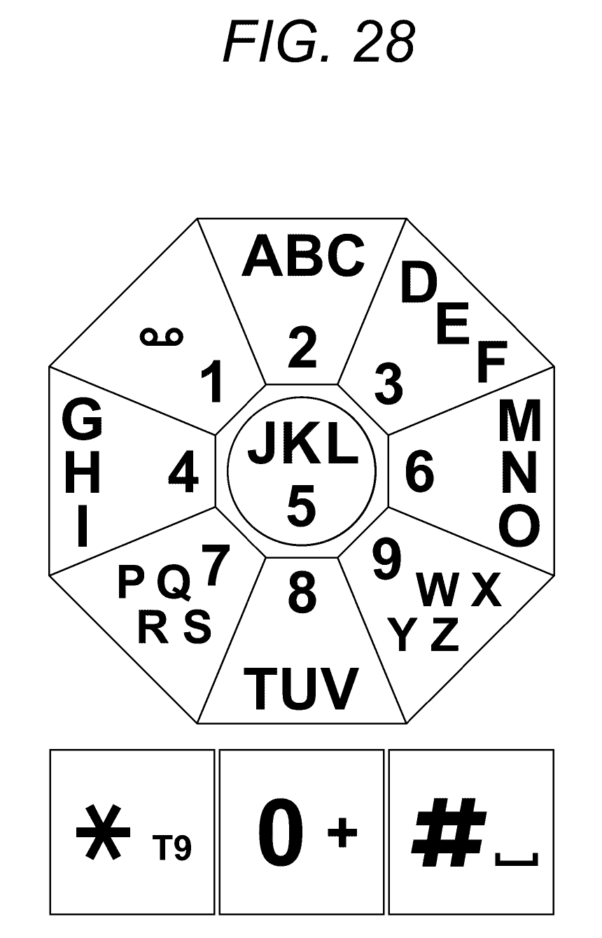

FIG. 29 shows a top view of one embodiment of the present invention using the prior art iPod menu key depicting a nine sensor keyboard where a centrally located sensor is surrounded by a disc shaped sensor with an eight surfaces for activation in eight cardinal point directions. Each of the nine sensors is numbered one through nine using the standard phone keypad numbering arrangement allowing for the placement of additional characters. Each of the nine sensors is labeled with three of twenty-six alphabetic characters and a space. The sensor numbered one is labeled with the space and two alphabetic characters.

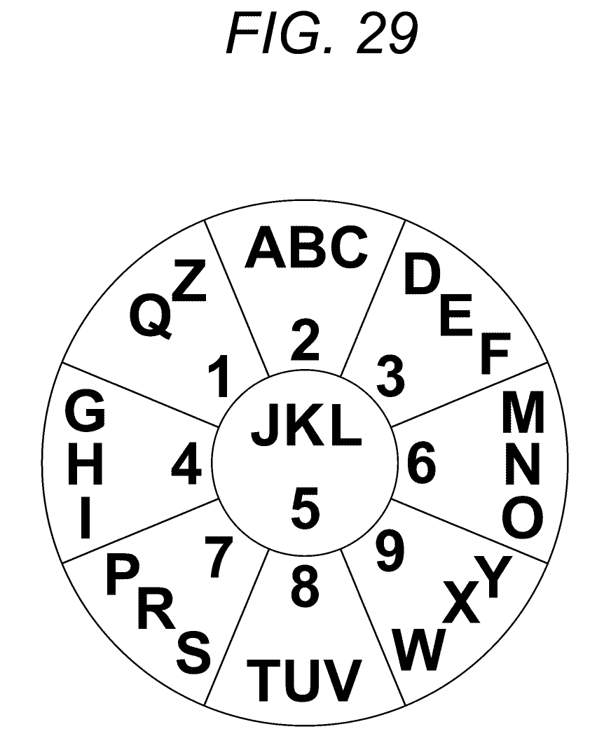

FIG. 30 shows a top view of one embodiment of the present invention using the prior art iPod menu key depicting a nine sensor keyboard where a centrally located sensor is surrounded by a disc shaped sensor with an eight surfaces for activation in eight cardinal point directions. Each of the nine sensors is numbered one through nine using the standard phone keypad numbering arrangement allowing for the placement of additional characters. Each of the nine sensors is labeled with three of twenty-six alphabetic characters and a space. The sensor numbered one is labeled with the space and two alphabetic characters. Each of the nine sensors is also labeled with three punctuation marks or symbols.

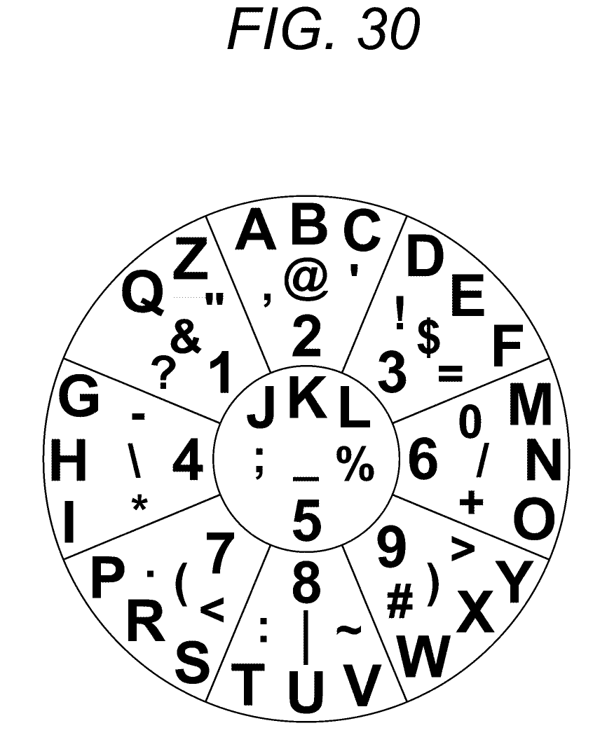

### DETAILED DESCRIPTION OF THE PREFERRED EMBODIMENT

In order too more fully understand the invention, during the course of this description, the nine sensor keyboard invention and preferred embodiments, will be labeled and explained to easily identify like elements according to the different figures which illustrate the invention. Additional objects of the present invention will become apparent as the description proceeds.

In the telephone industry, it is well known that the depression of any given sensor on the telephone keypad generates one of twelve pairs of audio tones on the “touch tone” phone, or its digital data counterpart on a digital phone. In the cell phone industry, it is well known that the text messaging standard uses a method of multi-tap to produce data. This invention takes advantage of the applicant's three issued patents; U.S. Pat. No. 6,043,761, U.S. Pat. No. 6,184,803 and U.S. Pat. No. 6,232,892, to produce a space on the [1] sensor or on the [0] sensor and the fact that all prior art (T9, iTAP and eZiText) programmed cell phones use the zero [0] sensor or the number [#] sensor to produce a space on cell phone keypads.

When any device is in the text messaging mode, the present invention produces at least twenty-six letters or characters, a space, numbers, punctuation and symbols using a centrally located sensor surrounded by eight adjacent sensors for activation in eight cardinal point directions, or a centrally located sensor surrounded by eight adjacent juxtaposed trapezoidal shaped sensors for activation in eight cardinal point directions, or a centrally located sensor surrounded by circular shaped sensor with eight touch sensor zones for activation in eight cardinal point directions. The use of a centrally located sensor surrounded by eight adjacent sensors activated by only one finger, preferably the thumb digit, produces the world's smallest data entry keyboard. Activating a centrally located sensor or one of the eight adjacent sensors once, twice, thrice, etc. produces the desired data. This method of producing data or text messaging can be used on a phone menu key, a camera menu sensor or an iPod/MP3 menu key. Combining the thumb keyboard with the applicant's three issued patents; U.S. Pat. No. 6,043,761, U.S. Pat. No. 6,184,803 and U.S. Pat. No. 6,232,892 produces a method of text messaging on any device faster than all prior art devices using any disclosed prior art. The present invention can use any of the prior art text messaging methods, but the applicant's three issued patents are the preferred input method due to the reduction in sensor activations required to produce data.

One preferred embodiment of the present invention includes:

A method of using a nine sensor keyboard for producing alphabetic data characters, data characters, a space, numbers, punctuation, symbols, control and functions using a centrally located touch activated sensor surrounded by eight adjacent cardinal point activated touch sensors. Activating a centrally located sensor or one of the eight adjacent sensors once produces the first preferably left position data, twice produces the second preferably middle position data and thrice produces the third preferably right position data, etc. Alternatively, activating a centrally located sensor or one of the eight adjacent sensors combined with the simultaneous activation of or followed by the sequential activation of a left preferred asterisk [*] sensor produces the first preferably left position data, activation of a middle preferred zero [0] sensor produces the second preferably middle position data, or activation of a right preferred number [#] sensor produces the third preferably right position data. Secondary activation of the second sensor, produces an upper-case letter.

The “a” is produced by activating one of the eight adjacent sensors surrounding the centrally located sensor in a north cardinal point direction once or by activating one of the eight adjacent sensors surrounding the centrally located sensor in a north cardinal point direction once combined with the simultaneous activation of or followed by the sequential activation of the left preferred asterisk [*] sensor. Activating the left preferred asterisk [*] sensor twice produces an upper-case “A”.

The “b” is produced by activating one of the eight adjacent sensors surrounding 24the centrally located sensor in a north cardinal point direction twice or by activating one of the eight adjacent sensors surrounding the centrally located sensor in a north cardinal point direction once combined with the simultaneous activation of or followed by the sequential activation of the middle preferred zero [0] sensor. Activating the middle preferred zero [0] sensor twice produces an upper-case “B”.

The “c” is produced by activating one of the eight adjacent sensors surrounding the centrally located sensor in a north cardinal point direction thrice or by activating one of the eight adjacent sensors surrounding the centrally located sensor in a north cardinal point direction once combined with the simultaneous activation of or followed by the sequential activation of the right preferred number [#] sensor. Activating the right preferred number [#] sensor twice produces an upper-case “C”.

The “d” is produced by activating one of the eight adjacent sensors surrounding the centrally located sensor in a north-east cardinal point direction once or by activating one of the eight adjacent sensors surrounding the centrally located sensor in a north-east cardinal point direction once combined with the simultaneous activation of or followed by the sequential activation of the left preferred asterisk [*] sensor. Activating the left preferred asterisk [*] sensor twice produces an upper-case “D”.

The “e” is produced by activating one of the eight adjacent sensors surrounding the centrally located sensor in a north-east cardinal point direction twice or by activating one of the eight adjacent sensors surrounding the centrally located sensor in a north-east cardinal point direction once combined with the simultaneous activation of or followed by the sequential activation of the middle preferred zero [0] sensor. Activating the middle preferred zero [0] sensor twice produces an upper-case “E”.

The “f” is produced by activating one of the eight adjacent sensors surrounding the centrally located sensor in a north-east cardinal point direction thrice or by activating one of the eight adjacent sensors surrounding the centrally located sensor in a north-east cardinal point direction once combined with the simultaneous activation of or followed by the sequential activation of the right preferred number [#] sensor. Activating the right preferred number [#] sensor twice produces an upper-case “F”.

The “g” is produced by activating one of the eight adjacent sensors surrounding the centrally located sensor in a west cardinal point direction once or by activating one of the eight adjacent sensors surrounding the centrally located sensor in a west cardinal point direction once combined with the simultaneous activation of or followed by the sequential activation of the left preferred asterisk [*] sensor. Activating the left preferred asterisk [*] sensor twice produces an upper-case “G”.

The “h” is produced by activating one of the eight adjacent sensors surrounding the centrally located sensor in a west cardinal point direction twice or by activating one of the eight adjacent sensors surrounding the centrally located sensor in a west cardinal point direction once combined with the simultaneous activation of or followed by the sequential activation of the middle preferred zero [0] sensor. Activating the middle preferred zero [0] sensor twice produces an upper-case “H”.

The “i” is produced by activating one of the eight adjacent sensors surrounding the centrally located sensor in a west cardinal point direction thrice or by activating one of the eight adjacent sensors surrounding the centrally located sensor in a west cardinal point direction once combined with the simultaneous activation of or followed by the sequential activation of the right preferred number [#] sensor. Activating the right preferred number [#] sensor twice produces an upper-case “I”.

The “j” is produced by activating a centrally located sensor once or by activating the centrally located sensor once combined with the simultaneous activation of or followed by the sequential activation of the right preferred asterisk [*] sensor. Activating the left preferred asterisk [*] sensor twice produces an upper-case “J”.

The “k” is produced by activating a centrally located sensor twice or by activating the centrally located sensor once combined with the simultaneous activation of or followed by the sequential activation of the right preferred zero [0] sensor. Activating the middle preferred zero [0] sensor twice produces an upper-case “K”.

The “l” is produced by activating a centrally located sensor thrice or by activating the centrally located sensor once combined with the simultaneous activation of or followed by the sequential activation of the right preferred number [#] sensor. Activating the right preferred number [#] sensor twice produces an upper-case “L”.

The “m” is produced by activating one of the eight adjacent sensors surrounding the centrally located sensor in an east cardinal point direction once or by activating one of the eight adjacent sensors surrounding the centrally located sensor in an east cardinal point direction once combined with the simultaneous activation of or followed by the sequential activation of the left preferred asterisk [*] sensor. Activating the left preferred asterisk [*] sensor twice produces an upper-case “M”.

The “n” is produced by activating one of the eight adjacent sensors surrounding the centrally located sensor in an east cardinal point direction twice or by activating one of the eight adjacent sensors surrounding the centrally located sensor in an east cardinal point direction once combined with the simultaneous activation of or followed by the sequential activation of the middle preferred zero [0] sensor. Activating the middle preferred zero [0] sensor twice produces an upper-case “N”.

The “o” is produced by activating one of the eight adjacent sensors surrounding the centrally located sensor in an east cardinal point direction thrice or by activating one of the eight adjacent sensors surrounding the centrally located sensor in an east cardinal point direction once combined with the simultaneous activation of or followed by the sequential activation of the right preferred number [#] sensor. Activating the right preferred number [#] sensor twice produces an upper-case “O”.

The “p” is produced by activating one of the eight adjacent sensors surrounding the centrally located sensor in a south-west cardinal point direction once or by activating one of the eight adjacent sensors surrounding the centrally located sensor in a south-west cardinal point direction once combined with the simultaneous activation of or followed by the sequential activation of the left preferred asterisk [*] sensor. Activating the left preferred asterisk [*] sensor twice produces an upper-case “P”.

The “q” is produced by activating one of the eight adjacent sensors surrounding the centrally located sensor in a north-west cardinal point direction twice or by activating one of the eight adjacent sensors surrounding the centrally located sensor in a north-west cardinal point direction once combined with the simultaneous activation of or followed by the sequential activation of the middle preferred zero [0] sensor. Activating the middle preferred zero [0] sensor twice produces an upper-case “Q”.

The “r” is produced by activating one of the eight adjacent sensors surrounding the centrally located sensor in a south-west cardinal point direction twice or by activating one of the eight adjacent sensors surrounding the centrally located sensor in a south-west cardinal point direction once combined with the simultaneous activation of or followed by the sequential activation of the middle preferred zero [0] sensor. Activating the middle preferred zero [0] sensor twice produces an upper-case “R”.

The “s” is produced by activating one of the eight adjacent sensors surrounding the centrally located sensor in a south-west cardinal point direction thrice or by activating one of the eight adjacent sensors surrounding the centrally located sensor in a south-west cardinal point direction once combined with the simultaneous activation of or followed by the sequential activation of the right preferred number [#] sensor. Activating the right preferred number [#] sensor twice produces an upper-case “S”.

The “t” is produced by activating one of the eight adjacent sensors surrounding the centrally located sensor in a south cardinal point direction once or by activating one of the eight adjacent sensors surrounding the centrally located sensor in a south cardinal point direction once combined with the simultaneous activation of or followed by the sequential activation of the left preferred asterisk [*] sensor. Activating the left preferred asterisk [*] sensor twice produces an upper-case “T”.

The “u” is produced by activating one of the eight adjacent sensors surrounding the centrally located sensor in a south cardinal point direction twice or by activating one of the eight adjacent sensors surrounding the centrally located sensor in a south cardinal point direction once combined with the simultaneous activation of or followed by the sequential activation of the middle preferred zero [0] sensor. Activating the middle preferred zero [0] sensor twice produces an upper-case “U”.

The “v” is produced by activating one of the eight adjacent sensors surrounding the centrally located sensor in a south cardinal point direction thrice or by activating one of the eight adjacent sensors surrounding the centrally located sensor in a south cardinal point direction once combined with the simultaneous activation of or followed by the sequential activation of the right preferred number [#] sensor. Activating the right preferred number [#] sensor twice produces an upper-case “V”.

The “w” is produced by activating one of the eight adjacent sensors surrounding the centrally located sensor in a south-east cardinal point direction once or by activating one of the eight adjacent sensors surrounding the centrally located sensor in a south-east cardinal point direction once combined with the simultaneous activation of or followed by the sequential activation of the left preferred asterisk [*] sensor. Activating the left preferred asterisk [*] sensor twice produces an upper-case “W”.

The “x” is produced by activating one of the eight adjacent sensors surrounding the centrally located sensor in a south-east cardinal point direction twice or by activating one of the eight adjacent sensors surrounding the centrally located sensor in a south-east cardinal point direction once combined with the simultaneous activation of or followed by the sequential activation of the middle preferred zero [0] sensor. Activating the middle preferred zero [0] sensor twice produces an upper-case “X”.

The “y” is produced by activating one of the eight adjacent sensors surrounding the centrally located sensor in a south-east cardinal point direction thrice or by activating one of the eight adjacent sensors surrounding the centrally located sensor in a south-east cardinal point direction once combined with the simultaneous activation of or followed by the sequential activation of the right preferred number [#] sensor. Activating the right preferred number [#] sensor twice produces an upper-case “Y”.

The “z” is produced by activating one of the eight adjacent sensors surrounding the centrally located sensor in a north-west cardinal point direction thrice or by activating one of the eight adjacent sensors surrounding the centrally located sensor in a north-west cardinal point direction once combined with the simultaneous activation of or followed by the sequential activation of the right preferred number [#] sensor. Activating the right preferred number [#] sensor twice produces an upper-case “Z”.

The “space” is produced by activating one of the eight adjacent sensors surrounding the centrally located sensor in a north-west cardinal point direction once, by activating one of the eight adjacent sensors surrounding the centrally located sensor in a north-west cardinal point direction once combined with the simultaneous activation of or followed by the sequential activation of the left preferred asterisk [*] sensor or by activating the middle preferred zero [0] sensor once.

The “1” is produced by activating one of the eight adjacent sensors surrounding the centrally located sensor in a north-west cardinal point direction four times.

The “2” is produced by activating one of the eight adjacent sensors surrounding the centrally located sensor in a north cardinal point direction four times.

The “3” is produced by activating one of the eight adjacent sensors surrounding the centrally located sensor in a north-east cardinal point direction four times.

The “4” is produced by activating one of the eight adjacent sensors surrounding the centrally located sensor in a west cardinal point direction four times.

The “5” is produced by activating a centrally located sensor four times.

The “6” is produced by activating one of the eight adjacent sensors surrounding the centrally located sensor in an east cardinal point direction four times.

The “7” is produced by activating one of the eight adjacent sensors surrounding the centrally located sensor in a south-west cardinal point direction four times.

The “8” is produced by activating one of the eight adjacent sensors surrounding the centrally located sensor in a south cardinal point direction four times.

The “9” is produced by activating one of the eight adjacent sensors surrounding the centrally located sensor in a south-east cardinal point direction four times.

The question mark “?” is produced by activating one of the eight adjacent sensors surrounding the centrally located sensor in a north-west cardinal point direction five times.

The comma “,” is produced by activating one of the eight adjacent sensors surrounding the centrally located sensor in a north cardinal point direction five times.

The exclamation mark “!” is produced by activating one of the eight adjacent sensors surrounding the centrally located sensor in a north-east cardinal point direction five times.

The hyphen “-” is produced by activating one of the eight adjacent sensors surrounding the centrally located sensor in a west cardinal point direction five times.

The semicolon “;” is produced by activating a centrally located sensor five times.

The zero “0” is produced by activating one of the eight adjacent sensors surrounding the centrally located sensor in an east cardinal point direction five times.

The period “.” is produced by activating one of the eight adjacent sensors surrounding the centrally located sensor in a south-west cardinal point direction five times.

The colon “:” is produced by activating one of the eight adjacent sensors surrounding the centrally located sensor in a south cardinal point direction five times.

The number sign “#” is produced by activating one of the eight adjacent sensors surrounding the centrally located sensor in a south-east cardinal point direction five times.

The ampersand “&” is produced by activating one of the eight adjacent sensors surrounding the centrally located sensor in a north-west cardinal point direction six times.

The at sign “@” is produced by activating one of the eight adjacent sensors surrounding the centrally located sensor in a north cardinal point direction six times.

The dollar sign “$” is produced by activating one of the eight adjacent sensors surrounding the centrally located sensor in a north-east cardinal point direction six times.

The backslash “\” is produced by activating one of the eight adjacent sensors surrounding the centrally located sensor in a west cardinal point direction six times.

The underscore “_” is produced by activating a centrally located sensor six times.

The slash “/” is produced by activating one of the eight adjacent sensors surrounding the centrally located sensor in an east cardinal point direction six times.

The left parenthesis “(” is produced by activating one of the eight adjacent sensors surrounding the centrally located sensor in a south-west cardinal point direction six times.

The vertical line “|” is produced by activating one of the eight adjacent sensors surrounding the centrally located sensor in a south cardinal point direction six times.

The right parenthesis “)” is produced by activating one of the eight adjacent sensors surrounding the centrally located sensor in a south-east cardinal point direction six times.

The quote ““” is produced by activating one of the eight adjacent sensors surrounding the centrally located sensor in a north-west cardinal point direction seven times.

The apostrophe “'” is produced by activating one of the eight adjacent sensors surrounding the centrally located sensor in a north cardinal point direction seven times.

The equals sign “=” is produced by activating one of the eight adjacent sensors surrounding the centrally located sensor in a north-east cardinal point direction seven times.

The asterisk “*” is produced by activating one of the eight adjacent sensors surrounding the centrally located sensor in a west cardinal point direction seven times.

The percent sign “%” is produced by activating a centrally located sensor seven times.

The plus sign “+” is produced by activating one of the eight adjacent sensors surrounding the centrally located sensor in an east cardinal point direction seven times.

The less than sign “<” is produced by activating one of the eight adjacent sensors surrounding the centrally located sensor in a south-west cardinal point direction seven times.

The tilde “˜” is produced by activating one of the eight adjacent sensors surrounding the centrally located sensor in a south cardinal point direction seven times.

The greater than sign “>” is produced by activating one of the eight adjacent sensors surrounding the centrally located sensor in a south-east cardinal point direction seven times.

Activating one of the eight adjacent sensors surrounding the centrally located sensor or the centrally located sensors eight times or more produces even more data characters, control or functions. Programming the device to produce the user's preferred data characters using preferred key activations is also possible.

Another preferred embodiment of the present invention includes:

A method of using a nine sensor keyboard for producing numbers one through nine, at least twenty-six data characters or letters of an alphabet and a space, punctuation and symbols using a centrally located touch activated sensor surrounded by eight adjacent touch activated sensors. Activating a centrally located sensor or one of the eight adjacent sensors once produces numbers one through nine, twice produces the first preferably left position data, thrice produces the second preferably middle position data and four times produces the third preferably right position data, etc. Alternatively, activating a centrally located sensor or one of the eight adjacent sensors combined with the simultaneous activation of or followed by the sequential activation of a left preferred asterisk [*] sensor produces the first preferably left position data, activation of a middle preferred zero [0] sensor produces the second preferably middle position data, or activation of a right preferred number [#] sensor produces the third preferably right position data. Secondary activation of the second sensor, produces an upper-case letter.

The “1” is produced by activating one of the eight adjacent sensors surrounding the centrally located sensor in a north-west cardinal point direction once.

The “2” is produced by activating one of the eight adjacent sensors surrounding the centrally located sensor in a north cardinal point direction once.

The “3” is produced by activating one of the eight adjacent sensors surrounding the centrally located sensor in a north-east cardinal point direction once.

The “4” is produced by activating one of the eight adjacent sensors surrounding the centrally located sensor in a west cardinal point direction once.

The “5” is produced by activating a centrally located sensor once.

The “6” is produced by activating one of the eight adjacent sensors surrounding the centrally located sensor in an east cardinal point direction once.

The “7” is produced by activating one of the eight adjacent sensors surrounding the centrally located sensor in a south-west cardinal point direction once.

The “8” is produced by activating one of the eight adjacent sensors surrounding the centrally located sensor in a south cardinal point direction once.

The “9” is produced by activating one of the eight adjacent sensors surrounding the centrally located sensor in a south-east cardinal point direction once.

The “a” is produced by activating one of the eight adjacent sensors surrounding the centrally located sensor in a north cardinal point direction twice or by activating one of the eight adjacent sensors surrounding the centrally located sensor in a north cardinal point direction once combined with the simultaneous activation of or followed by the sequential activation of the left preferred asterisk [*] sensor. Activating the left preferred asterisk [*] sensor twice produces an upper-case “A”.

The “b” is produced by activating one of the eight adjacent sensors surrounding the centrally located sensor in a north cardinal point direction thrice or by activating one of the eight adjacent sensors surrounding the centrally located sensor in a north cardinal point direction once combined with the simultaneous activation of or followed by the sequential activation of the middle preferred zero [0] sensor. Activating the middle preferred zero [0] sensor twice produces an upper-case “B”.

The “c” is produced by activating one of the eight adjacent sensors surrounding the centrally located sensor in a north cardinal point direction four times or by activating one of the eight adjacent sensors surrounding the centrally located sensor in a north cardinal point direction once combined with the simultaneous activation of or followed by the sequential activation of the right preferred number [#] sensor. Activating the right preferred number [#] sensor twice produces an upper-case “C”.

The “d” is produced by activating one of the eight adjacent sensors surrounding the centrally located sensor in a north-east cardinal point direction twice or by activating one of the eight adjacent sensors surrounding the centrally located sensor in a north-east cardinal point direction once combined with the simultaneous activation of or followed by the sequential activation of the left preferred asterisk [*] sensor. Activating the left preferred asterisk [*] sensor twice produces an upper-case “D”.

The “e” is produced by activating one of the eight adjacent sensors surrounding the centrally located sensor in a north-east cardinal point direction thrice or by activating one of the eight adjacent sensors surrounding the centrally located sensor in a north-east cardinal point direction once combined with the simultaneous activation of or followed by the sequential activation of the middle preferred zero [0] sensor. Activating the middle preferred zero [0] sensor twice produces an upper-case “E”.

The “f” is produced by activating one of the eight adjacent sensors surrounding the centrally located sensor in a north-east cardinal point direction four times or by activating one of the eight adjacent sensors surrounding the centrally located sensor in a north-east cardinal point direction once combined with the simultaneous activation of or followed by the sequential activation of the right preferred number [#] sensor. Activating the right preferred number [#] sensor twice produces an upper-case “F”.

The “g” is produced by activating one of the eight adjacent sensors surrounding the centrally located sensor in a west cardinal point direction twice or by activating one of the eight adjacent sensors surrounding the centrally located sensor in a west cardinal point direction once combined with the simultaneous activation of or followed by the sequential activation of the left preferred asterisk [*] sensor. Activating the left preferred asterisk [*] sensor twice produces an upper-case “G”.

The “h” is produced by activating one of the eight adjacent sensors surrounding the centrally located sensor in a west cardinal point direction thrice or by activating one of the eight adjacent sensors surrounding the centrally located sensor in a west cardinal point direction once combined with the simultaneous activation of or followed by the sequential activation of the middle preferred zero [0] sensor. Activating the middle preferred zero [0] sensor twice produces an upper-case “H”.

The “i” is produced by activating one of the eight adjacent sensors surrounding the centrally located sensor in a west cardinal point direction four times or by activating one of the eight adjacent sensors surrounding the centrally located sensor in a west cardinal point direction once combined with the simultaneous activation of or followed by the sequential activation of the right preferred number [#] sensor. Activating the right preferred number [#] sensor twice produces an upper-case “I”.

The “j” is produced by activating a centrally located sensor twice or by activating the centrally located sensor once combined with the simultaneous activation of or followed by the sequential activation of the right preferred asterisk [*] sensor. Activating the left preferred asterisk [*] sensor twice produces an upper-case “J”.

The “k” is produced by activating a centrally located sensor thrice or by activating the centrally located sensor once combined with the simultaneous activation of or followed by the sequential activation of the right preferred zero [0] sensor. Activating the middle preferred zero [0] sensor twice produces an upper-case “K”.

The “l” is produced by activating a centrally located sensor four times or by activating the centrally located sensor once combined with the simultaneous activation of or followed by the sequential activation of the right preferred number [#] sensor. Activating the right preferred number [#] sensor twice produces an upper-case “L”.

The “m” is produced by activating one of the eight adjacent sensors surrounding the centrally located sensor in an east cardinal point direction twice or by activating one of the eight adjacent sensors surrounding the centrally located sensor in an east cardinal point direction once combined with the simultaneous activation of or followed by the sequential activation of the left preferred asterisk [*] sensor. Activating the left preferred asterisk [*] sensor twice produces an upper-case “M”.

The “n” is produced by activating one of the eight adjacent sensors surrounding the centrally located sensor in an east cardinal point direction thrice or by activating one of the eight adjacent sensors surrounding the centrally located sensor in an east cardinal point direction once combined with the simultaneous activation of or followed by the sequential activation of the middle preferred zero [0] sensor. Activating the middle preferred zero [0] sensor twice produces an upper-case “N”.

The “o” is produced by activating one of the eight adjacent sensors surrounding the centrally located sensor in an east cardinal point direction four times or by activating one of the eight adjacent sensors surrounding the centrally located sensor in an east cardinal point direction once combined with the simultaneous activation of or followed by the sequential activation of the right preferred number [#] sensor. Activating the right preferred number [#] sensor twice produces an upper-case “O”.

The “p” is produced by activating one of the eight adjacent sensors surrounding the centrally located sensor in a south-west cardinal point direction twice or by activating one of the eight adjacent sensors surrounding the centrally located sensor in a south-west cardinal point direction once combined with the simultaneous activation of or followed by the sequential activation of the left preferred asterisk [*] sensor. Activating the left preferred asterisk [*] sensor twice produces an upper-case “P”.

The “q” is produced by activating one of the eight adjacent sensors surrounding the centrally located sensor in a north-west cardinal point direction thrice or by activating one of the eight adjacent sensors surrounding the centrally located sensor in a north-west cardinal point direction once combined with the simultaneous activation of or followed by the sequential activation of the middle preferred zero [0] sensor. Activating the middle preferred zero [0] sensor twice produces an upper-case “Q”.

The “r” is produced by activating one of the eight adjacent sensors surrounding the centrally located sensor in a south-west cardinal point direction thrice or by activating one of the eight adjacent sensors surrounding the centrally located sensor in a south-west cardinal point direction once combined with the simultaneous activation of or followed by the sequential activation of the middle preferred zero [0] sensor. Activating the middle preferred zero [0] sensor twice produces an upper-case “R”.

The “s” is produced by activating one of the eight adjacent sensors surrounding the centrally located sensor in a south-west cardinal point direction four times or by activating one of the eight adjacent sensors surrounding the centrally located sensor in a south-west cardinal point direction once combined with the simultaneous activation of or followed by the sequential activation of the right preferred number [#] sensor. Activating the right preferred number [#] sensor twice produces an upper-case “S”.

The “t” is produced by activating one of the eight adjacent sensors surrounding the centrally located sensor in a south cardinal point direction twice or by activating one of the eight adjacent sensors surrounding the centrally located sensor in a south cardinal point direction once combined with the simultaneous activation of or followed by the sequential activation of the left preferred asterisk [*] sensor. Activating the left preferred asterisk [*] sensor twice produces an upper-case “T”.

The “u” is produced by activating one of the eight adjacent sensors surrounding the centrally located sensor in a south cardinal point direction thrice or by activating one of the eight adjacent sensors surrounding the centrally located sensor in a south cardinal point direction once combined with the simultaneous activation of or followed by the sequential activation of the middle preferred zero [0] sensor. Activating the middle preferred zero [0] sensor twice produces an upper-case “U”.

The “v” is produced by activating one of the eight adjacent sensors surrounding the centrally located sensor in a south cardinal point direction four times or by activating one of the eight adjacent sensors surrounding the centrally located sensor in a south cardinal point direction once combined with the simultaneous activation of or followed by the sequential activation of the right preferred number [#] sensor. Activating the right preferred number [#] sensor twice produces an upper-case “V”.

The “w” is produced by activating one of the eight adjacent sensors surrounding the centrally located sensor in a south-east cardinal point direction twice or by activating one of the eight adjacent sensors surrounding the centrally located sensor in a south-east cardinal point direction once combined with the simultaneous activation of or followed by the sequential activation of the left preferred asterisk [*] sensor. Activating the left preferred asterisk [*] sensor twice produces an upper-case “W”.

The “x” is produced by activating one of the eight adjacent sensors surrounding the centrally located sensor in a south-east cardinal point direction thrice or by activating one of the eight adjacent sensors surrounding the centrally located sensor in a south-east cardinal point direction once combined with the simultaneous activation of or followed by the sequential activation of the middle preferred zero [0] sensor. Activating the middle preferred zero [0] sensor twice produces an upper-case “X”.

The “y” is produced by activating one of the eight adjacent sensors surrounding the centrally located sensor in a south-east cardinal point direction four times or by activating one of the eight adjacent sensors surrounding the centrally located sensor in a south-east cardinal point direction once combined with the simultaneous activation of or followed by the sequential activation of the right preferred number [#] sensor. Activating the right preferred number [#] sensor twice produces an upper-case “Y”.

The “z” is produced by activating one of the eight adjacent sensors surrounding the centrally located sensor in a north-west cardinal point direction four times or by activating one of the eight adjacent sensors surrounding the centrally located sensor in a north-west cardinal point direction once combined with the simultaneous activation of or followed by the sequential activation of the right preferred number [#] sensor. Activating the right preferred number [#] sensor twice produces an upper-case “Z”.

The “space” is produced by activating one of the eight adjacent sensors surrounding the centrally located sensor in a north-west cardinal point direction once, by activating one of the eight adjacent sensors surrounding the centrally located sensor in a north-west cardinal point direction once combined with the simultaneous activation of or followed by the sequential activation of the left preferred asterisk [*] sensor or by activating the middle preferred zero [0] sensor once.

The question mark “?” is produced by activating one of the eight adjacent sensors surrounding the centrally located sensor in a north-west cardinal point direction five times.

The comma “,” is produced by activating one of the eight adjacent sensors surrounding the centrally located sensor in a north cardinal point direction five times.

The exclamation mark “!” is produced by activating one of the eight adjacent sensors surrounding the centrally located sensor in a north-east cardinal point direction five times.

The hyphen “-” is produced by activating one of the eight adjacent sensors surrounding the centrally located sensor in a west cardinal point direction five times.

The semicolon “;” is produced by activating a centrally located sensor five times.

The zero “0” is produced by activating one of the eight adjacent sensors surrounding the centrally located sensor in an east cardinal point direction five times.

The period “.” is produced by activating one of the eight adjacent sensors surrounding the centrally located sensor in a south-west cardinal point direction five times.

The colon “:” is produced by activating one of the eight adjacent sensors surrounding the centrally located sensor in a south cardinal point direction five times.

The number sign “#” is produced by activating one of the eight adjacent sensors surrounding the centrally located sensor in a south-east cardinal point direction five times.

The ampersand “&” is produced by activating one of the eight adjacent sensors surrounding the centrally located sensor in a north-west cardinal point direction six times.

The at sign “@” is produced by activating one of the eight adjacent sensors surrounding the centrally located sensor in a north cardinal point direction six times.

The dollar sign “$” is produced by activating one of the eight adjacent sensors surrounding the centrally located sensor in a north-east cardinal point direction six times.

The backslash “\” is produced by activating one of the eight adjacent sensors surrounding the centrally located sensor in a west cardinal point direction six times.

The underscore “_” is produced by activating a centrally located sensor six times.

The slash “/” is produced by activating one of the eight adjacent sensors surrounding the centrally located sensor in an east cardinal point direction six times.

The left parenthesis “(” is produced by activating one of the eight adjacent sensors surrounding the centrally located sensor in a south-west cardinal point direction six times.

The vertical line “|” is produced by activating one of the eight adjacent sensors surrounding the centrally located sensor in a south cardinal point direction six times.

The right parenthesis “)” is produced by activating one of the eight adjacent sensors surrounding the centrally located sensor in a south-east cardinal point direction six times.

The quote ““” is produced by activating one of the eight adjacent sensors surrounding the centrally located sensor in a north-west cardinal point direction seven times.

The apostrophe “'” is produced by activating one of the eight adjacent sensors surrounding the centrally located sensor in a north cardinal point direction seven times.

The equals sign “=” is produced by activating one of the eight adjacent sensors surrounding the centrally located sensor in a north-east cardinal point direction seven times.

The asterisk “*” is produced by activating one of the eight adjacent sensors surrounding the centrally located sensor in a west cardinal point direction seven times.

The percent sign “%” is produced by activating a centrally located sensor seven times.

The plus sign “+” is produced by activating one of the eight adjacent sensors surrounding the centrally located sensor in an east cardinal point direction seven times.

The less than sign “<” is produced by activating one of the eight adjacent sensors surrounding the centrally located sensor in a south-west cardinal point direction seven times.

The tilde “˜” is produced by activating one of the eight adjacent sensors surrounding the centrally located sensor in a south cardinal point direction seven times.

The greater than sign “>” is produced by activating one of the eight adjacent sensors surrounding the centrally located sensor in a south-east cardinal point direction seven times.

Activating one of the eight adjacent sensors surrounding the centrally located sensor or the centrally located sensors eight times or more produces even more data characters, control or functions. Programming the device to produce the user's preferred data characters using preferred key activations is also possible.

Another preferred embodiment of the present invention includes:

A method of using a nine sensor keyboard for producing numbers one through nine, at least twenty-six data characters or letters of an alphabet and a space, punctuation and symbols using a centrally located touch activated sensor surrounded by eight adjacent touch activated sensors. Activating a centrally located sensor or one of the eight adjacent sensors once produces numbers one through nine. Alternatively, activating a centrally located sensor or one of the eight adjacent sensors combined with the simultaneous activation of or followed by the sequential activation of a left preferred asterisk [*] sensor produces the first preferably left position data, activation of a middle preferred zero [0] sensor produces the second preferably middle position data, or activation of a right preferred number [#] sensor produces the third preferably right position data. Secondary activation of the second sensor, produces an upper-case letter. Activating a centrally located sensor or one of the eight adjacent sensors combined with the simultaneous activation of or followed by the sequential activation of a left sensor ([1], [4] or [7]) produces the left position data, activation of a middle sensor ([2], [5] or [8]) produces the middle position data, or activation of a right sensor ([3], [6] or [9]) produces the right position data.

The “1” is produced by activating one of the eight adjacent sensors surrounding the centrally located sensor in a north-west cardinal point direction once.

The “2” is produced by activating one of the eight adjacent sensors surrounding the centrally located sensor in a north cardinal point direction once.

The “3” is produced by activating one of the eight adjacent sensors surrounding the centrally located sensor in a north-east cardinal point direction once.

The “4” is produced by activating one of the eight adjacent sensors surrounding the centrally located sensor in a west cardinal point direction once.

The “5” is produced by activating a centrally located sensor once.

The “6” is produced by activating one of the eight adjacent sensors surrounding the centrally located sensor in an east cardinal point direction once.

The “7” is produced by activating one of the eight adjacent sensors surrounding the centrally located sensor in a south-west cardinal point direction once.

The “8” is produced by activating one of the eight adjacent sensors surrounding the centrally located sensor in a south cardinal point direction once.

The “9” is produced by activating one of the eight adjacent sensors surrounding the centrally located sensor in a south-east cardinal point direction once.

The “a” is produced by activating one of the eight adjacent sensors surrounding the centrally located sensor in a north cardinal point direction combined with the simultaneous activation of or followed by the sequential activation of the left preferred asterisk [*] sensor. Activating the left preferred asterisk [*] sensor twice produces an upper-case “A”.

The “b” is produced by activating one of the eight adjacent sensors surrounding the centrally located sensor in a north cardinal point direction combined with the simultaneous activation of or followed by the sequential activation of the middle preferred zero [0] sensor. Activating the middle preferred zero [0] sensor twice produces an upper-case “B”.

The “c” is produced by activating one of the eight adjacent sensors surrounding the centrally located sensor in a north cardinal point direction combined with the simultaneous activation of or followed by the sequential activation of the right preferred number [#] sensor. Activating the right preferred number [#] sensor twice produces an upper-case “C”.

The “d” is produced by activating one of the eight adjacent sensors surrounding the centrally located sensor in a north-east cardinal point direction combined with the simultaneous activation of or followed by the sequential activation of the left preferred asterisk [*] sensor. Activating the left preferred asterisk [*] sensor twice produces an upper-case “D”.

The “e” is produced by activating one of the eight adjacent sensors surrounding the centrally located sensor in a north-east cardinal point direction combined with the simultaneous activation of or followed by the sequential activation of the middle preferred zero [0] sensor. Activating the middle preferred zero [0] sensor twice produces an upper-case “E”.

The “f” is produced by activating one of the eight adjacent sensors surrounding the centrally located sensor in a north-east cardinal point direction combined with the simultaneous activation of or followed by the sequential activation of the right preferred number [#] sensor. Activating the right preferred number [#] sensor twice produces an upper-case “F”.

The “g” is produced by activating one of the eight adjacent sensors surrounding the centrally located sensor in a west cardinal point direction combined with the simultaneous activation of or followed by the sequential activation of the left preferred asterisk [*] sensor. Activating the left preferred asterisk [*] sensor twice produces an upper-case “G”.

The “h” is produced by activating one of the eight adjacent sensors surrounding the centrally located sensor in a west cardinal point direction combined with the simultaneous activation of or followed by the sequential activation of the middle preferred zero [0] sensor. Activating the middle preferred zero [0] sensor twice produces an upper-case “H”.

The “I” is produced by activating one of the eight adjacent sensors surrounding the centrally located sensor in a west cardinal point direction combined with the simultaneous activation of or followed by the sequential activation of the right preferred number [#] sensor. Activating the right preferred number [#] sensor twice produces an upper-case “I”.

The “j” is produced by activating a centrally located sensor twice or by activating the centrally located sensor combined with the simultaneous activation of or followed by the sequential activation of the right preferred asterisk [*] sensor. Activating the left preferred asterisk [*] sensor twice produces an upper-case “J”.

The “k” is produced by activating a centrally located sensor thrice or by activating the centrally located sensor combined with the simultaneous activation of or followed by the sequential activation of the right preferred zero [0] sensor. Activating the middle preferred zero [0] sensor twice produces an upper-case “K”.

The “l” is produced by activating a centrally located sensor four times or by activating the centrally located sensor combined with the simultaneous activation of or followed by the sequential activation of the right preferred number [#] sensor. Activating the right preferred number [#] sensor twice produces an upper-case “L”.

The “m” is produced by activating one of the eight adjacent sensors surrounding the centrally located sensor in an east cardinal point direction combined with the simultaneous activation of or followed by the sequential activation of the left preferred asterisk [*] sensor. Activating the left preferred asterisk [*] sensor twice produces an upper-case “M”.

The “n” is produced by activating one of the eight adjacent sensors surrounding the centrally located sensor in an east cardinal point direction combined with the simultaneous activation of or followed by the sequential activation of the middle preferred zero [0] sensor. Activating the middle preferred zero [0] sensor twice produces an upper-case “N”.

The “o” is produced by activating one of the eight adjacent sensors surrounding the centrally located sensor in an east cardinal point direction combined with the simultaneous activation of or followed by the sequential activation of the right preferred number [#] sensor. Activating the right preferred number [#] sensor twice produces an upper-case “O”.

The “p” is produced by activating one of the eight adjacent sensors surrounding the centrally located sensor in a south-west cardinal point direction combined with the simultaneous activation of or followed by the sequential activation of the left preferred asterisk [*] sensor. Activating the left preferred asterisk [*] sensor twice produces an upper-case “P”.

The “q” is produced by activating one of the eight adjacent sensors surrounding the centrally located sensor in a north-west cardinal point direction combined with the simultaneous activation of or followed by the sequential activation of the middle preferred zero [0] sensor. Activating the middle preferred zero [0] sensor twice produces an upper-case “Q”.

The “r” is produced by activating one of the eight adjacent sensors surrounding the centrally located sensor in a south-west cardinal point direction combined with the simultaneous activation of or followed by the sequential activation of the middle preferred zero [0] sensor. Activating the middle preferred zero [0] sensor twice produces an upper-case “R”.

The “s” is produced by activating one of the eight adjacent sensors surrounding the centrally located sensor in a south-west cardinal point direction combined with the simultaneous activation of or followed by the sequential activation of the right preferred number [#] sensor. Activating the right preferred number [#] sensor twice produces an upper-case “S”.

The “t” is produced by activating one of the eight adjacent sensors surrounding the centrally located sensor in a south cardinal point direction combined with the simultaneous activation of or followed by the sequential activation of the left preferred asterisk [*] sensor. Activating the left preferred asterisk [*] sensor twice produces an upper-case “T”.

The “u” is produced by activating one of the eight adjacent sensors surrounding the centrally located sensor in a south cardinal point direction combined with the simultaneous activation of or followed by the sequential activation of the middle preferred zero [0] sensor. Activating the middle preferred zero [0] sensor twice produces an upper-case “U”.

The “v” is produced by activating one of the eight adjacent sensors surrounding the centrally located sensor in a south cardinal point direction combined with the simultaneous activation of or followed by the sequential activation of the right preferred number [#] sensor. Activating the right preferred number [#] sensor twice produces an upper-case “V”.

The “w” is produced by activating one of the eight adjacent sensors surrounding the centrally located sensor in a south-east cardinal point direction combined with the simultaneous activation of or followed by the sequential activation of the left preferred asterisk [*] sensor. Activating the left preferred asterisk [*] sensor twice produces an upper-case “W”.

The “x” is produced by activating one of the eight adjacent sensors surrounding the centrally located sensor in a south-east cardinal point direction combined with the simultaneous activation of or followed by the sequential activation of the middle preferred zero [0] sensor. Activating the middle preferred zero [0] sensor twice produces an upper-case “X”.

The “y” is produced by activating one of the eight adjacent sensors surrounding the centrally located sensor in a south-east cardinal point direction combined with the simultaneous activation of or followed by the sequential activation of the right preferred number [#] sensor. Activating the right preferred number [#] sensor twice produces an upper-case “Y”.

The “z” is produced by activating one of the eight adjacent sensors surrounding the centrally located sensor in a north-west cardinal point direction combined with the simultaneous activation of or followed by the sequential activation of the right preferred number [#] sensor. Activating the right preferred number [#] sensor twice produces an upper-case “Z”.

The “space” is produced by activating one of the eight adjacent sensors surrounding the centrally located sensor in a north-west cardinal point direction combined with the simultaneous activation of or followed by the sequential activation of the left preferred asterisk [*] sensor or by activating the middle preferred zero [0] sensor once.

The question mark “?” is produced by activating one of the eight adjacent sensors surrounding the centrally located sensor in a north-west cardinal point direction combined with the simultaneous activation of or followed by the sequential activation of a left [1], [4] or [7] sensor.

The comma “,” is produced by activating one of the eight adjacent sensors surrounding the centrally located sensor in a north cardinal point direction combined with the simultaneous activation of or followed by the sequential activation of a left [1], [4] or [7] sensor.

The exclamation mark “!” is produced by activating one of the eight adjacent sensors surrounding the centrally located sensor in a north-east cardinal point direction combined with the simultaneous activation of or followed by the sequential activation of a left [1], [4] or [7] sensor.

The hyphen “-” is produced by activating one of the eight adjacent sensors surrounding the centrally located sensor in a west cardinal point direction combined with the simultaneous activation of or followed by the sequential activation of a left [1], [4] or [7] sensor.

The semicolon “;” is produced by activating a centrally located sensor combined with the simultaneous activation of or followed by the sequential activation of a left [1], [4] or [7] sensor.

The zero “0” is produced by activating one of the eight adjacent sensors surrounding the centrally located sensor in an east cardinal point direction combined with the simultaneous activation of or followed by the sequential activation of a left [1], [4] or [7] sensor.

The period “.” is produced by activating one of the eight adjacent sensors surrounding the centrally located sensor in a south-west cardinal point direction combined with the simultaneous activation of or followed by the sequential activation of a left [1], [4] or [7] sensor.

The colon “:” is produced by activating one of the eight adjacent sensors surrounding the centrally located sensor in a south cardinal point direction combined with the simultaneous activation of or followed by the sequential activation of a left [1], [4] or [7] sensor.

The number sign “#” is produced by activating one of the eight adjacent sensors surrounding the centrally located sensor in a south-east cardinal point direction combined with the simultaneous activation of or followed by the sequential activation of a left [1], [4] or [7] sensor.

The ampersand “&” is produced by activating one of the eight adjacent sensors surrounding the centrally located sensor in a north-west cardinal point direction combined with the simultaneous activation of or followed by the sequential activation of a middle [2], [5] or [8] sensor.

The at sign “@” is produced by activating one of the eight adjacent sensors surrounding the centrally located sensor in a north cardinal point direction combined with the simultaneous activation of or followed by the sequential activation of a middle [2], [5] or [8] sensor.

The dollar sign “$” is produced by activating one of the eight adjacent sensors surrounding the centrally located sensor in a north-east cardinal point direction combined with the simultaneous activation of or followed by the sequential activation of a middle [2], [5] or [8] sensor.

The backslash “\” is produced by activating one of the eight adjacent sensors surrounding the centrally located sensor in a west cardinal point direction combined with the simultaneous activation of or followed by the sequential activation of a middle [2], [5] or [8] sensor.

The underscore “_” is produced by activating a centrally located sensor combined with the simultaneous activation of or followed by the sequential activation of a middle [2], [5] or [8] sensor.

The slash “/” is produced by activating one of the eight adjacent sensors surrounding the centrally located sensor in an east cardinal point direction combined with the simultaneous activation of or followed by the sequential activation of a middle [2], [5] or [8] sensor.

The left parenthesis “(” is produced by activating one of the eight adjacent sensors surrounding the centrally located sensor in a south-west cardinal point direction combined with the simultaneous activation of or followed by the sequential activation of a middle [2], [5] or [8] sensor.

The vertical line “|” is produced by activating one of the eight adjacent sensors surrounding the centrally located sensor in a south cardinal point direction combined with the simultaneous activation of or followed by the sequential activation of a middle [2], [5] or [8] sensor.

The right parenthesis “)” is produced by activating one of the eight adjacent sensors surrounding the centrally located sensor in a south-east cardinal point direction combined with the simultaneous activation of or followed by the sequential activation of a middle [2], [5] or [8] sensor.

The quote ““” is produced by activating one of the eight adjacent sensors surrounding the centrally located sensor in a north-west cardinal point direction combined with the simultaneous activation of or followed by the sequential activation of a right [3], [6] or [9] sensor.

The apostrophe “'” is produced by activating one of the eight adjacent sensors surrounding the centrally located sensor in a north cardinal point direction combined with the simultaneous activation of or followed by the sequential activation of a right [3], [6] or [9] sensor.

The equals sign “=” is produced by activating one of the eight adjacent sensors surrounding the centrally located sensor in a north-east cardinal point direction combined with the simultaneous activation of or followed by the sequential activation of a right [3], [6] or [9] sensor.

The asterisk “*” is produced by activating one of the eight adjacent sensors surrounding the centrally located sensor in a west cardinal point direction combined with the simultaneous activation of or followed by the sequential activation of a right [3], [6] or [9] sensor.

The percent sign “%” is produced by activating a centrally located sensor combined with the simultaneous activation of or followed by the sequential activation of a right [3], [6] or [9] sensor.

The plus sign “+” is produced by activating one of the eight adjacent sensors surrounding the centrally located sensor in an east cardinal point direction combined with the simultaneous activation of or followed by the sequential activation of a right [3], [6] or [9] sensor.

The less than sign “<” is produced by activating one of the eight adjacent sensors surrounding the centrally located sensor in a south-west cardinal point direction combined with the simultaneous activation of or followed by the sequential activation of a right [3], [6] or [9] sensor.

The tilde “˜” is produced by activating one of the eight adjacent sensors surrounding the centrally located sensor in a south cardinal point direction combined with the simultaneous activation of or followed by the sequential activation of a right [3], [6] or [9] sensor.

The greater than sign “>” is produced by activating one of the eight adjacent sensors surrounding the centrally located sensor in a south-east cardinal point direction combined with the simultaneous activation of or followed by the sequential activation of a right [3], [6] or [9] sensor.

Extra punctuation marks, symbols and functions are produced by activating the centrally located sensor or one of the eight adjacent sensors surrounding the centrally located sensor in eight cardinal point directions more than one time.

Alternatively, any letter data, numeric data, punctuation data, symbol data or any other type of data or character substitution can be made or used for the present invention's described text input methods and alternative preferred embodiments.

In another preferred embodiment of the present invention, when using the centrally located sensor surrounded by eight adjacent sensors to produce data on a phone or cell phone, activating any sensor other than the centrally located sensor surrounded by eight adjacent sensors enters the entered data for the production of the next data character located on the same sensor as the previously entered data character.

In another preferred embodiment of the present invention, activating a centrally located sensor or one of the eight adjacent sensors combined with the simultaneous activation of or followed by the sequential activation of a left preferred [1], [4], [7] or [*] sensor produces the first preferably left position data, activation of a middle preferred [2], [5], [8] or [0] sensor produces the second preferably middle position data, or activation of a right preferred [3], [6], [9] or [#] sensor produces the third preferably right position data.

In another preferred embodiment of the present invention, when using the centrally located sensor surrounded by eight adjacent sensors to produce data on a phone or cell phone, activating the left preferred asterisk [*] sensor when using only the centrally located sensor surrounded by eight adjacent sensors to produce alphabetic data, while in an alphabetic multi-tap mode, produces an upper-case data character.

In another preferred embodiment of the present invention, when using the centrally located sensor surrounded by eight adjacent sensors to produce data on a phone or cell phone, activating the left preferred asterisk [*] sensor once produces a period “.”, activating the middle preferred zero [0] sensor once produces a space “ ”, activating the right preferred number [#] sensor once produces a hyphen “-”.

In another preferred embodiment of the present invention, numbers are produced by activating one of the ten numbered sensors.

In another preferred embodiment of the present invention, to produce a backspace while in the number mode, the right preferred number [#] sensor is activated once, when it is not followed by the sequential activation of a first left preferred asterisk [*] sensor or a second middle preferred zero [0] sensor.

In another preferred embodiment of the present invention, activation of the right preferred number [#] sensor three times, while in the alphanumeric mode, produces the “ENTER/RETURN/SEND” function.

In another preferred embodiment of the present invention, activation of the left preferred asterisk [*] sensor, while in the number mode, when not followed by the sequential activation of middle preferred zero [0] sensor or the activation of the right preferred number [#] sensor, exits the number mode and enters an alphabet mode.

In another preferred embodiment of the present invention, activation of the left preferred asterisk [*] sensor followed by the secondary activation of the left preferred asterisk [*] sensor, when not followed by the sequential activation of middle preferred zero [0] sensor or the activation of the right preferred number [#] sensor, while in the number mode, exits the number mode and enters a two sensor lower-case alphabet mode and a three sensor upper-case alphabet mode, where the secondary activation of the second sensor produces the upper-case character.

In another preferred embodiment of the present invention, activation of the middle preferred zero [0] sensor two times, while in an alphabetic mode, produces the “TAB” function.

In another preferred embodiment of the present invention, activation of the left preferred asterisk [*] sensor, while in an alphabetic mode, followed by the left preferred asterisk [*] sensor, deletes the previously-entered bit of data, otherwise known as the backspace.

In another preferred embodiment of the present invention, activation of the left preferred asterisk [*] sensor three times, while in an alphabetic mode, deletes the previously entered word.

In another preferred embodiment of the present invention, activation of the left preferred asterisk [*] sensor, while in an alphabetic mode, combined with the simultaneous activation of or followed by the sequential activation of the middle preferred zero [0] sensor produces a period “.”.

In another preferred embodiment of the present invention, activation of the left preferred asterisk [*] sensor, while in the alphabetic mode, combined with the simultaneous activation of or followed by the sequential activation of the activation of the right preferred number [#] sensor enters a one-time use punctuation mode, followed by the desired punctuation data sensor representation of the ten sensors numbered one [1] through zero [0], where the activation of the preferred [1] sensor produces a question mark “?”, where the activation of the preferred [2] sensor produces a comma “,”, where the activation of the preferred [3] sensor produces an exclamation mark “!”, where the activation of the preferred [4] sensor produces a hyphen “-”, where the activation of the preferred [5] sensor produces a semicolon “;”, where the activation of the preferred [6] sensor produces a zero “0”, where the activation of the preferred [7] sensor produces a period “.”, where the activation of the preferred [8] sensor produces a colon “:”, where the activation of the preferred [9] sensor produces a number sign “#”, where the activation of the preferred [0] sensor produces an at sign “@”. After producing a punctuation mark the device returns to the previous alphabetic mode.

In another preferred embodiment of the present invention, activation of the right preferred number [#] sensor combined with the simultaneous activation of or followed by the sequential activation of the middle preferred zero [0] sensor, while in the alphabetic mode, returns the keyboard to the number mode.

These and other features of the present invention will be more fully understood by referencing the drawings.

In summary, the present invention and many preferred embodiments of the present invention all use a centrally located sensor surrounded by eight adjacent cardinal point activated sensors or eight touch sensor cardinal point activated zones to produce alphabetic data characters, data characters, a space, numbers, punctuation, symbols, control and functions, preferably activated by the left or right thumb. The centrally located sensor surrounded by eight adjacent sensors, activated by one digit on a user's hand, is the smallest keyboard in the history of mankind and fulfills the need for blind text messaging and one handed text messaging. Three or six additional sensors provide a reduction in the number of key activations for producing simultaneous or sequential sensor activations.

While the present invention disclosed has been described with reference to the preferred embodiments thereof, a latitude of modification, change, and substitution is intended in the foregoing disclosure, and in some instances, some features of the invention will be employed without a corresponding use of the inventions other features. Accordingly, it will be appreciated by those having an ordinary skill in the art that various modifications can be made to the system of the invention and it is appropriate that the description and appended claims are construed broadly and in a manner consistent with the spirit and scope of the invention herein without departing from the spirit and scope of the invention as a whole.

1. A nine sensor keyboard comprising:
a) a centrally located sensor surrounded by eight adjacent sensors; and
b) said eight adjacent sensors are activated in eight cardinal point directions; and
c) each sensor of said nine sensors is used to produce one of twenty-six data characters or a space; or numbers one through nine; or a zero, punctuation or symbols.

2. A nine sensor keyboard, in accordance with claim 1, wherein:
each sensor of said nine sensors is used to produce a number one through nine when activated once.

3. A nine sensor keyboard, in accordance with claim 1, wherein:
each sensor of said nine sensors is used to produce a number one through nine when sequentially activated four times.

4. A nine sensor keyboard, in accordance with claim 1, wherein:
each sensor of said nine sensors is used to produce one of twenty-six data characters or a space when activated once.

5. A nine sensor keyboard, in accordance with claim 1, wherein:
each sensor of said nine sensors is used to produce a zero, a punctuation mark or a symbol when activated more than once.

6. A nine sensor keyboard, in accordance with claim 1, wherein:
each sensor of said nine sensors is used to produce a symbol when activated more than once.

7. A nine sensor keyboard, in accordance with claim 1, wherein:
each sensor of said nine sensors sequentially or simultaneously activated with one sensor of three additional sensors is used to produce one of twenty-six data characters or a space.

8. A nine sensor keyboard, in accordance with claim 1, wherein:
a) each sensor of said nine sensors is used to produce a number one through nine when activated once; and
b) each sensor of said nine sensors sequentially or simultaneously activated with one sensor of three additional sensors is used to produce one of twenty-six data characters or a space.

9. A nine sensor keyboard, in accordance with claim 1, wherein:
a) each sensor of said nine sensors is used to produce a number one through nine when activated once; and
b) each sensor of said nine sensors sequentially or simultaneously activated with one sensor of three additional sensors is used to produce a zero, a punctuation mark or a symbol.

10. A nine sensor keyboard comprising:
a) a circular shaped sensor having a centrally located hole; and
b) said circular shaped sensor having eight cardinal point direction touch sensor zones forming eight sensors for eight sensor activation; and
c) centrally located ninth sensor inside said centrally located hole inside said circular shaped sensor; and
d) each sensor of said nine sensors is used to produce one of twenty-six data characters and a space; or nine numbers one through nine; or a zero, punctuation or symbols.

11. A nine sensor keyboard, in accordance with claim 10, wherein:
each sensor of said nine sensors is used to produce a number one through nine when activated once.

12. A nine sensor keyboard, in accordance with claim 10, wherein:
each sensor of said nine sensors is used to produce a number one through nine when sequentially activated four times.

13. A nine sensor keyboard, in accordance with claim 10, wherein:
each sensor of said nine sensors is used to produce one of twenty-six data characters or a space when activated once.

14. A nine sensor keyboard, in accordance with claim 10, wherein:
each sensor of said nine sensors is used to produce a punctuation mark or a zero when activated more than once.

15. A nine sensor keyboard, in accordance with claim 10, wherein:
each sensor of said nine sensors is used to produce a symbol when activated more than once.

16. A nine sensor keyboard, in accordance with claim 10, wherein:
each sensor of said nine sensors sequentially or simultaneously activated with one sensor of three additional sensors is used to produce one of twenty-six data characters or a space.

17. A nine sensor keyboard, in accordance with claim 10, wherein:
a) each sensor of said nine sensors is used to produce a number one through nine when activated once; and
b) each sensor of said nine sensors sequentially or simultaneously activated with one sensor of three additional sensors is used to produce one of twenty-six data characters or a space.

18. A nine sensor keyboard, in accordance with claim 10, wherein:
a) each sensor of said nine sensors is used to produce a number one through nine when activated once; and
b) each sensor of said nine sensors sequentially or simultaneously activated with one sensor of three additional sensors is used to produce a zero, a punctuation mark or a symbol.

19. A nine sensor keyboard comprising:
a) a centrally located sensor surrounded by eight adjacent sensors; and
b) each sensor of said nine sensors is used to produce a number one through nine; and
c) each sensor of said nine sensors simultaneously or sequentially activated with any one sensor of a first set of three additional sensors is used to produce one of twenty-six data characters or a space; and
d) each sensor of said nine sensors simultaneously or sequentially activated with any one sensor of a second set of three additional sensors is used to produce a zero, a punctuation mark or a symbol.

20. A nine sensor keyboard, in accordance with claim 19, wherein:
a) any one sensor of said first set of three additional sensors is used to produce a data character, a null state or a function; and
b) any one sensor of said first set of three additional sensors sequentially or simultaneously activated with a second sensor of said first set of three additional sensors is used to produce a data character, a null state or a function; and
c) any one sensor of said second set of three additional sensors is used to produce a data character, a null state or a function; and
d) any one sensor of said second set of three additional sensors sequentially or simultaneously activated with a second sensor of said second set of three additional sensors is used to produce a data character, a null state or a function.
